(19) United States
(12) Patent Application Publication
(10) Pub. No.: US 2025/0174569 A1
(43) Pub. Date: May 29, 2025

(54) CROSSTALK REDUCTION USING TRACE COUPLING IN INTEGRATED CIRCUIT COMPONENTS

(71) Applicant: MICROSOFT TECHNOLOGY LICENSING, LLC, Redmond, WA (US)

(72) Inventors: Gong OUYANG, Redmond, WA (US); Afshin JOOSHESH, Bellevue, WA (US); Charles Caldwell PHARES, Seattle, WA (US)

(21) Appl. No.: 18/521,474

(22) Filed: Nov. 28, 2023

(51) Int. Cl. H01L 23/538; G06F 30/32; H01L 25/18; H05K 1/02; H10B 80/00

(52) U.S. Cl. CPC H01L 23/5386; G06F 30/32; H05K 1/0228; H05K 1/0245; H01L 25/18; H05K 2201/10159; H10B 80/00

(57) ABSTRACT

Aspects of the embodiments disclosed herein include electrical systems that reduce crosstalk, such as far-end crosstalk (FEXT) between two or more signal paths of a memory system by electromagnetically coupling the two or more signal paths each comprising a respective trace. Electromagnetically coupling the two or more respective traces includes positioning at least two traces in close proximity with each other such that a mutual-to-self-inductance ratio (Lm/L) between the at least two signal paths matches or substantially matches the mutual-to-self-capacitance ratio (Cm/C) of the at least two signal paths. Certain embodiments of this disclosure are directed to a passive manner of reducing FEXT between any number of signal paths without adding traces with the sole purpose of reducing crosstalk, thereby reducing or maintaining a signal density between designs of a component of an IC package.

### BACKGROUND

In the context of the storage of data for access by computer systems, what began as a large six-foot tall disk storage device was replaced by much smaller hard disk drives. In general, hard disk drives (HDDs) are traditional storage devices with spinning platters that read and write data. Whereas HDDs utilize mechanical spinning disks and moving read/write heads to access data, integrated circuit (IC) packages generally use smaller memory chips storing information on random-access memory (RAM) devices, such as dynamic random-access memory (DRAM) devices, without any mechanical spinning disks. As computing demand increased, those HDDs were later replaced by certain IC packages that are smaller, faster, quieter, and more durable than HDDs.

Moreover, the growth of cloud computing technology and, more recently, artificial intelligence (AI), has led to the more widespread adoption of compact IC packages in certain datacenters and consumer electronics. In certain contexts, IC packages have been favored over HDDs for their efficient and compact storage, leading to a recent increased reliance on IC packages for certain storage and computing functionality. As demand for memory bandwidth and capacity increases, memory systems face one issue: crosstalk. Crosstalk is generally caused by electromagnetic interference between closely placed communication lines in silicon, IC packages, and printed circuit boards, leading to noise and certain errors in data transmission. This problem is intensified in certain memory systems due to high frequencies and parallel data transmission. Despite certain mitigation technique, crosstalk remains an issue in memory system design as higher memory performance continues to be an industry goal.

### SUMMARY

Various aspects of the technology described herein are generally directed to systems, methods, and computer storage media for, among other things, reducing crosstalk, such as far-end crosstalk (FEXT), between two or more signal paths of a memory system by electromagnetically coupling the two or more traces. Electromagnetically coupling the two or more traces includes positioning at least two traces in close proximity with each other such that a mutual-to-self-inductance ratio (Lm/L) between the at least two signal paths matches or substantially matches the mutual-to-self-capacitance ratio (Cm/C) of the at least two signal paths. Taking two traces of an integrated circuit (IC) package as an example, electromagnetically coupling a first trace and a second trace includes causing the first trace or second trace to generate a crosstalk canceling pulse having an amplitude substantially similar and a polarity opposite of the crosstalk between the first signal path and the second signal path, which the first trace and the second trace are part of, respectively.

Aspects of the embodiments disclosed herein reduce crosstalk by coupling at least two traces that serve a function beyond merely reducing crosstalk. Aspects of the embodiments disclosed herein include an IC system, such as an IC package or a component of the IC package, that includes at least two traces, such as a first trace and a second trace. The first trace extends, within the IC system, between a first end and a second end, and a first signal travels along the first trace from the first end to the second end. Embodiments of the first trace have a shape defined, between the first end and the second end, by a first segment, a second segment, and a third segment. The second trace extends, within the IC system, between a corresponding first end and a corresponding second end, and a second signal travels along the second trace. The second trace has a shape defined by a corresponding first segment, a corresponding second segment, and a corresponding third segment. The corresponding second segment of the second trace electromagnetically couples with the second segment of the first trace to reduce a far-end crosstalk (FEXT) between the first trace and the second trace by controlling the first signal to cause the first signal to travel along the second segment in a direction opposite of the second signal traveling along the corresponding second segment of the second trace. The electromagnetic coupling is achieved by designing the corresponding second segment of the second trace to cause the corresponding second segment to generate a crosstalk canceling pulse having an amplitude substantially similar and a polarity opposite of the FEXT between the first signal path and the second signal path.

Accordingly, embodiments of this disclosure at least partially remedy the technical shortcomings of certain existing circuitry associated with electronic devices, such as components of an IC package. Certain embodiments of this disclosure reduce FEXT between any number of traces without adding traces with the sole purpose of reducing crosstalk, thereby reducing or maintaining a signal density between designs of a component of an IC package. Moreover, electromagnetically coupling traces causes two or more traces within a component of the IC package to be brought closer together with each other, thereby reducing the size of a component of the IC package, allowing increased computational capabilities as compared to devices of similar size. Moreover, this increased computational efficiency, reduced FEXT, and smaller-sized design can be scaled across IC packages without adding unnecessary, isolated traces by electromagnetically coupling two or more traces, as disclosed herein.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

The technology described herein is described in detail below with reference to the attached drawing figures, wherein:

FIG. 1A depicts a block diagram of an example integrated circuit package suitable for use in implementing aspects of the technology described herein;

FIG. 1B depicts a schematic diagram showing a cross-sectional view of an example integrated circuit package, in accordance with aspects of the technology described herein;

FIG. 1C depicts a schematic diagram showing two traces carrying respective signals, in accordance with aspects of the technology described herein;

FIG. 2A depicts a schematic diagram showing two traces that form a coupling trace pair having an out-of-phase coupling relationship, in accordance with aspects of the technology described herein;

FIG. 2B depicts a schematic diagram showing the flow of current between the two traces of FIG. 2A that form a coupling trace pair having the out-of-phase coupling relationship, in accordance with aspects of the technology described herein;

FIG. 3A depicts a schematic diagram showing two traces that form a coupling trace pair having an in-phase coupling relationship, in accordance with aspects of the technology described herein;

FIG. 3B depicts a schematic diagram showing the flow of current between the two traces of FIG. 3A that form a coupling trace pair having the in-phase coupling relationship, in accordance with aspects of the technology described herein;

FIG. 4A depicts a schematic diagram showing two traces that form a coupling trace pair and that have two loops at two adjacent planes, in accordance with aspects of the technology described herein;

FIG. 4B depicts a schematic diagram showing two traces that form a coupling trace pair and that have two loops on the same plane, in accordance with aspects of the technology described herein;

FIG. 4C depicts a schematic diagram showing two traces that form a coupling trace pair and that have two loops each at distinct vertical positions, in accordance with aspects of the technology described herein;

FIG. 4D depicts a schematic diagram showing two traces that form a coupling trace pair and that have coupling trace pairs with sharp corners, in accordance with aspects of the technology described herein;

FIG. 5A depicts a first circuit diagram showing two traces that are not electromagnetically coupled in the segments highlighted by the dashed rectangular box, in accordance with aspects of the technology described herein;

FIG. 5B depicts a second circuit diagram showing two traces that are electromagnetically coupled in an out-of-phase inductive relationship in the segments highlighted by the dashed rectangular box, in accordance with aspects of the technology described herein;

FIG. 5C depicts a third circuit diagram showing two traces that are inductively coupled in an in-phase inductive coupling relationship in the segments highlighted by the dashed rectangular box, in accordance with aspects of the technology described herein;

FIG. 5D depicts a heat map of two magnetic field contour plots associated with the second circuit diagram of FIG. 5B or the third circuit diagram of FIG. 5C, in accordance with aspects of the technology described herein;

FIG. 6A depicts a schematic diagram of a system including a plurality of traces that each form a plurality of coupling trace pairs, in accordance with aspects of the technology described herein;

FIG. 6B depicts a schematic diagram of a system including a plurality of traces that each form at least one coupling trace pairs, in accordance with aspects of the technology described herein;

FIG. 7A depicts a schematic diagram of a first system including two example differential pairs of traces that form a coupling trace pair between the two differential signal pairs, in accordance with aspects of the technology described herein;

FIG. 7B depicts a schematic diagram of a second system including two example differential pairs of traces that form a coupling trace pair between the two differential signal pairs, in accordance with aspects of the technology described herein;

FIG. 8 depicts an example method to modify a proposed design layout of an integrated circuit package or a printed circuit board (PCB) to generate an updated proposed design layout experiencing less FEXT as compared to the proposed design layout, in accordance with aspects of the technology described herein;

FIG. 9A depicts an example embodiment of the present disclosure that has been reduced to practice, including an example IC package that was tested and simulated in accordance with aspects of the technology described herein;

FIG. 9B depicts insertion loss results of the example embodiment from FIG. 9A that has been reduced to practice, tested, and simulated, in accordance with aspects of the technology described herein;

FIG. 9C depicts far-end crosstalk (FEXT) results of the example embodiment from FIG. 9A that has been reduced to practice, tested, and simulated, in accordance with aspects of the technology described herein;

FIG. 10A depicts a voltage step response associated with the example embodiment from FIG. 9A that has been reduced to practice, in accordance with aspects of the technology described herein;

FIG. 10B depicts a crosstalk response associated with the example embodiment from FIG. 9A that has been reduced to practice, in accordance with aspects of the technology described herein;

FIG. 11A depicts an eye diagram showing a time-domain simulation for a full-channel that does not employ aspect of the embodiments disclosed herein;

FIG. 11B depicts an eye diagram showing a time-domain simulation for a full-channel corresponding to the example embodiment from FIG. 9A that has been reduced to practice, tested, and simulated;

FIG. 12 depicts a block diagram of an example distributed computing environment suitable for use in implementing aspects of the technology described herein; and

FIG. 13 is a block diagram of an example computing device suitable for use in implementing aspects of the technology described herein.

### DETAILED DESCRIPTION OF THE DISCLOSURE

The subject matter of aspects of the present disclosure is described with specificity herein to meet statutory requirements. However, the description itself is not intended to limit the scope of this patent. Rather, this disclosure contemplates that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described. Each method described herein may comprise a computing process that may be performed using any combination of hardware, firmware, and/or software. For instance, various functions may be carried out by a processor executing instructions stored in memory. The methods may also be embodied as computer-usable instructions stored on computer storage media. The methods may be provided by a standalone application, a service or hosted service (standalone or in combination with another hosted service), or a plug-in to another product, to name a few.

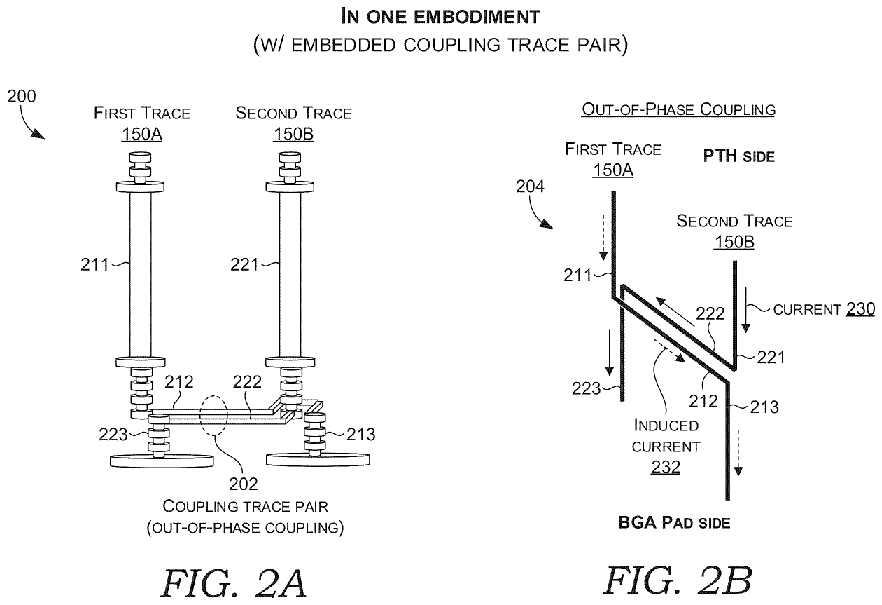

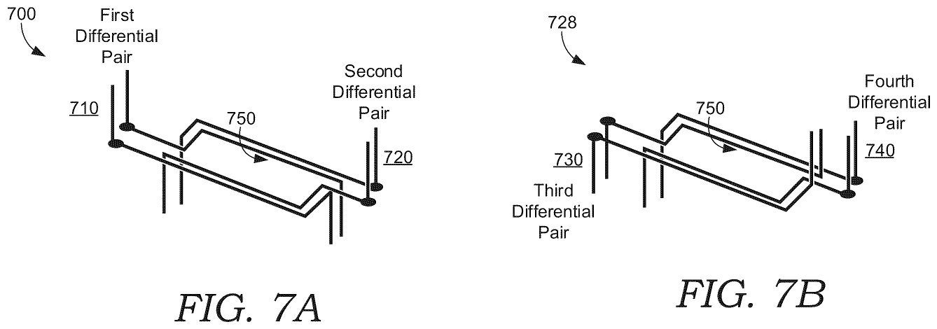

Various aspects of the technology described herein are generally directed to systems, methods, and computer storage media for, among other things, reducing crosstalk, such as far-end crosstalk (FEXT), between two or more traces of a memory system by electromagnetically coupling the two or more traces. In one example, a “trace” refers to a wire or conductive path that carries or communicates a signal along the conductive path from one electrical component to another electrical component to electrically coupling the two electrical components. In one example, the “trace” refers to a portion of the “signal path” carrying the corresponding signal. In one example, the trace connects to the pins or pads with solder, for example, to further direct the corresponding signal along the signal path. In one example, the term “trace” includes multiple conductive paths, such as those forming a “differential pair,” illustrated in FIGS. 7A and 7B. The conductive path may be of any suitable shape, such as a shape having straight portions, curved portions, or any combination thereof, along any suitable three-dimensional (3D) or two-dimensional (2D) path, such as those illustrated in FIGS. 2A, 3A, 4A, 4B, 4C, and 4D. An example trace includes a lead electrically coupling a component external to an IC package to a component of, on, internal to, or within the IC package. In another example, the trace includes an internal conductive path electrically coupling components of, on, internal to, or within the IC package.

In one example, “electromagnetically coupling” the two or more traces includes positioning at least two traces in close proximity with each other such that a mutual-to-self-inductance ratio (Lm/L) between the at least two signal paths, which two traces are part of respectively, matches or substantially matches the mutual-to-self-capacitance ratio (Cm/C) of the at least two signal paths, which the two traces are part of respectively. In one example, the electromagnetic coupling is an inductive and capacitance effect between the at least two traces, of which more of the effect is inductive. In one example, “close proximity” of two traces refers to a distance between the two traces being less than or equal to 50 microns, such as 50 microns, 30 microns, 25 microns, 15 microns, and so forth, or any value in between. However, other distances are also possible, such as 100, 300, and 500 microns, and so forth, especially when more than two traces are electromagnetically coupled.

Increased efforts have been made to decrease the size while increasing the capabilities of circuitry, memory devices, computers, and other electronics. Doing so poses numerous challenges because expanding electronic functionality, increasing computational capabilities, and improving response speed typically requires hardware components to be added into these devices. The addition of these hardware components increases the trace count of the electronic device. In the context of small integrated circuit (IC) packages, the small size of these devices and the large number of traces within the IC packages can cause crosstalk. In general, “crosstalk” is the unwanted coupling or disturbance caused by the electric or magnetic fields of one telecommunication signal of one trace affecting another telecommunication signal in an adjacent trace. In some instances, crosstalk prevents certain electronic components, such as memory buses, from running at a higher speed and at higher levels of efficiency. One existing solution to reduce crosstalk is to keep signals far away from each other. However, this solution increases the size and cost of certain IC packages and in some instances is not realistic given the size of certain IC packages. Another existing solution to reduce crosstalk is to add more ground pins to increase isolation between traces and their corresponding signals. However, this solution is costly and requires additional components (for example, the ground pins) to be packed into an IC package with already limited real estate.

With this in mind, aspects of the embodiments disclosed herein reduce crosstalk by coupling at least two traces that serve a function beyond merely reducing crosstalk. Taking two traces of an integrated circuit (IC) package as an example, electromagnetically coupling a first trace and a second trace includes causing the first trace or second trace to generate a crosstalk canceling pulse having an amplitude substantially similar and a polarity opposite of the crosstalk between the first trace and the second trace. Certain embodiments disclosed herein do not add a grounding pin to an IC package with the intent of merely using the added grounding pin to isolate traces. Instead, certain aspects of the embodiments disclosed herein include an IC package having traces that have respective portions in close proximity to each other and that transmit signals that (1) communicatively couple components (for example, a receiver and transceiver within the IC package) and that (2) additionally generate the crosstalk canceling pulse.

In this manner, embodiments of this disclosure preserve a signal density of an IC package between a first version of a design for the IC package and a second design of the IC package, thereby reducing crosstalk without adding a trace or grounding pin to different versions of the IC package designs. As used herein in one example, “signal density” refers to the concentration of signals within a given area or volume of the IC package. As such, signal density can be a measure of how many signals or components are packed into a specific space of the IC package. In one embodiment, increasing the size (for example, length) of a trace does not increase the signal density, for example, because the increased size of the trace may reduce a quantity of signals in a given space, and the increased size of the trace does not necessarily increase a magnitude of the signal.

Embodiments of this disclosure include an IC system that includes at least two traces, such as a first trace and a second trace. In some embodiments, the first trace extends, within the IC system, between a first end and a second end, and a first signal travels along the first trace from the first end to the second end. Embodiments of the first trace have a shape defined, between the first end and the second end, by a first segment, a second segment, and/or a third segment. In some embodiments, the second trace extends, within the IC system, between a corresponding first end and a corresponding second end, and a second signal travels along the second trace. Embodiments of the second trace have a shape defined by a corresponding first segment, a corresponding second segment, and a corresponding third segment. In some embodiments, the corresponding second segment of the second trace electromagnetically couples with the second segment of the first trace to reduce a far-end crosstalk (FEXT) between the first trace and the second trace.

In some embodiment, the FEXT caused by cross-talk between signal paths, such as a first signal path and a second signal path, is reduced by a cross-cancelation pulse (also referred to in one example, as the “second induced current”) generated or induced by a trace pair, such as a trace pair formed by a first trace and a second trace. In one example, the first signal path includes the first trace and the second signal path includes the second trace. In one example, the FEXT is reduced by controlling the first signal to cause the first signal to travel along the second segment in a direction opposite of the second signal traveling along the corresponding second segment of the second trace. For example, the FEXT is reduced by controlling the first signal to cause the first signal to travel along the second segment in a direction that induces a second induced current in the corresponding second segment of the second trace, such that the second induced current is induced in a direction opposite of a first induced current traveling along the corresponding second segment of the second trace. In one example, the first induced current occurs outside the first trace and the second trace (for example, in other areas of the first signal path or the second signal path). For example, the first induced current occurs as a result of electro-magnetic coupling between two portions (for example, between the first signal path and the second signal path) in other locations, such as at a package region other than the two traces, socket, PCB, connector, silicon, and so forth. In one embodiment, the electromagnetic coupling is achieved by designing the corresponding second segment of the second trace to cause the corresponding second segment to generate a crosstalk canceling pulse having an amplitude substantially similar and a polarity opposite of the FEXT between the first trace and the second trace.

Embodiments of this disclosure include a method for redesigning the IC package or portion thereof. In one embodiment, redesigning the IC package is an iterative process that is achieved after the FEXT is below a threshold value. In one embodiment, the method for redesigning the IC package or portion thereof includes receiving a proposed design layout for a portion of an integrated circuit package. From the proposed design layout, embodiments of this disclosure determine traces in proximity to each other within the portion of the integrated circuit package. In one embodiment, the proposed design layout is digitally simulated based on the traces. Based on a digital simulation of the traces, embodiments of this disclosure determine crosstalk inducement between a first trace of the plurality of traces and a second trace of the plurality of traces. In one embodiment, a position within the component of the integrated circuit package for positioning a pair of coupling trace segments of the first trace and the second trace is determined. For example, the position of the pair of coupling trace segments is the position at which the pair of coupling traces are electromagnetically coupled as described herein. In some embodiments, the proposed design layout is modified to generate an updated proposed design layout including the pair of coupling trace segments within the portion of the integrated circuit package.

Accordingly, embodiments of this disclosure at least partially remedy the technical shortcomings of certain existing circuitry associated with electronic devices, such as components of an IC package. Certain embodiments of this disclosure reduce FEXT between any number of traces without adding grounding pins or other extra components with the sole purpose of reducing crosstalk. In this manner, certain embodiments of this disclosure provide a passive solution to reduce or maintain a signal density between designs of a component of an IC package. Accordingly, in some instances, the material additions required to implement this embodiment can be zero, thereby facilitating scaling the implementation of these embodiments. Moreover, electromagnetically coupling traces causes two or more traces within a component of the IC package to be brought closer together with each other, thereby reducing the size of a component of the IC package, allowing increased computational capabilities as compared to devices of similar size. Moreover, this increased computational efficiency, reduced FEXT, and smaller-sized design can be scaled across IC packages without adding unnecessary, isolated traces by electromagnetically coupling two or more traces, as disclosed herein.

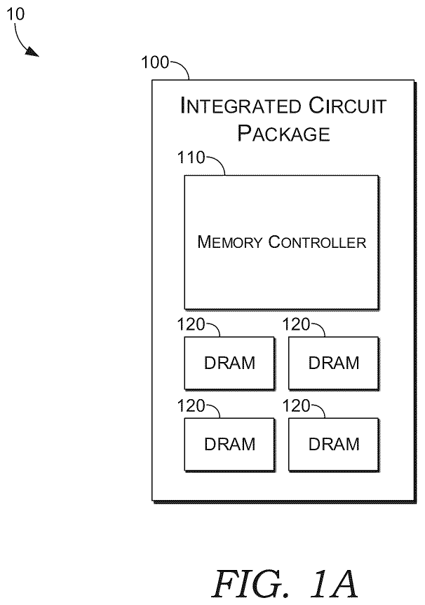

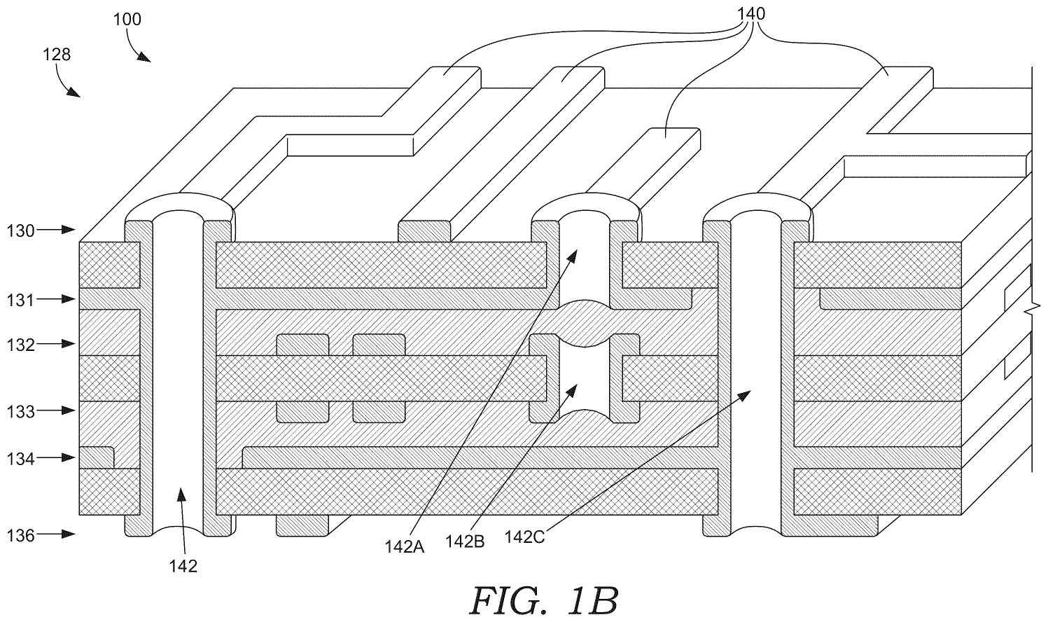

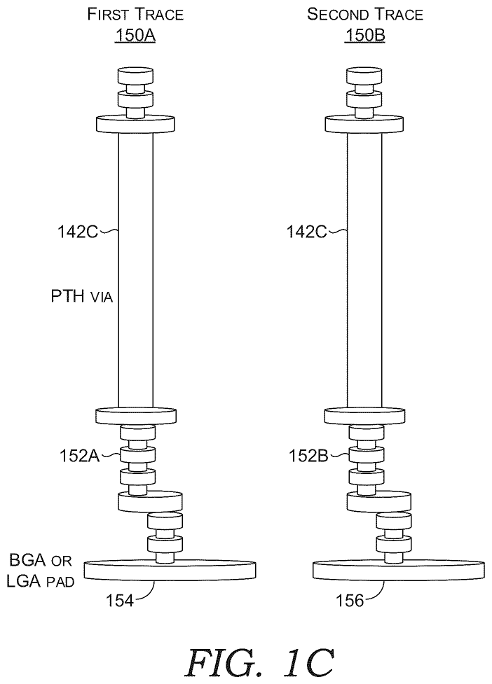

Aspects of the technical solution can be described by way of examples and with reference to the figures. FIG. 1A illustrates an example system 10 that includes an IC package 100 suitable for use in implementing aspects of the technology described herein. As illustrated, the example IC package 100 includes a memory controller 110 and a plurality of DRAM 120.

In some embodiments, the memory controller 110 includes circuitry that uses electrical signals to direct the entire IC to execute stored program instructions. In one embodiment, the memory controller 110 does not directly execute program instructions; rather, the memory controller 110 directs other parts of the system to do so. For example, the memory controller 110 directs the DRAM 120 to execute arithmetic and logical operations. In one embodiment, the memory controller 110 includes electronic circuitry that executes arithmetic and logical operations, such as those discussed herein. In some embodiments, the memory controller 110 performs any number of arithmetic operations, or mathematical calculations, such as addition, subtraction, multiplication, and division. Additionally, in some embodiments, the memory controller 110 also performs logical operations, such as comparisons of any data elements such as numbers, letters, or special characters, to name a few. Other logical operations that can be performed by the memory controller 110 include, among others, equal-to operations, less-than operations, greater-than operations, less-than-or-equal-to operations, greater-than-or-equal-to operations, and not-equal operations.

In one example, DRAM 120 refers to a random-access semiconductor memory that stores each bit of data in a memory cell, usually consisting of a small capacitor and a transistor. In some embodiments, DRAM 120 accesses data, generally in less than 10 microseconds, and is used to accelerate applications that would otherwise be held back by the latency of certain solid-state drives (SSDs) or traditional HDDs. One of the largest applications for DRAM 120 is the main memory (colloquially called the random-access memory or “RAM”) in certain computers and graphics cards (where the “main memory” is referred to as the graphics memory). DRAMs 120 can also be used in many portable devices and video game consoles. Although the DRAMs 120 are illustrated as being contained or integrated within IC package 100, it should be understood that in certain embodiments the DRAMs 120 are external to the IC package 100, are removably coupled to the IC package 100, or are separate from the IC package 100.

To achieve communications between the components of the IC package 100, such as the memory controller 110 and the DRAMs 120, any suitable computer bus employing any number of traces can be employed. For example, a computer bus transferring data on any variation of the rising and/or falling of edges of the clock signal can be employed. Example, computer buses include a single data rate (SDR) transferring one signal per clock cycle; a double data rate (DDR) transferring two signals per clock cycle; a quad data rate (QDR) transferring four signals per clock cycle; and so forth. The embodiments disclosed herein reduce a FEXT associated with two or more signals suffering from interference. In some embodiments, components external to the IC package 100 can interface with the components of the IC package 100 via leads (which is a type of trace, in one example). Indeed, although this example is discussed in the context of memory controller 110 and DRAMs being communicatively coupled to each other to allow the transmission of signals via a computer bus, it should be understood that components external to the IC package 100 can communicate with components within the IC package 100.

Additionally, although FIG. 1A is described in the context of an IC package 100 having specific components, various embodiments disclosed herein are applicable to other electronic devices, such as SSDs. In one example, the SSD 122 is a modular memory device having DRAMs and NAND (Not AND) flash devices, among other devices. Example SSDs include those manufactured or configured by enterprises associated with ATP®, INTEL®, KIOXIA®, MICRON®, NVIDIA®, and SAMSUNG ELECTRONICS®, among many others.

FIG. 1B depicts a schematic diagram showing a cross-sectional view of an example integrated circuit package 100, in accordance with aspects of the technology described herein. In one embodiment, the integrated circuit package 100 corresponds to a printed circuit board (PCB) 128. As illustrated, the IC package 100 includes six layers, but the embodiments described herein are applicable to IC packages 100 having any number of layers. The illustrated IC package 100 includes a top layer 130, a first midlayer 131, a second midlayer 132, a third midlayer 133, a fourth midlayer 134, and a bottom layer 136. In this example, the top layer 130 includes any number of surface traces 140 made of any suitable conductive material, such as copper, gold, or aluminum. Embodiments of the top layer 130 allow electronic components external to the IC package 100 to be electrically coupled to the top layer 130 by way of leads or pins on the external electronic component. In one embodiment, the first midlayer 131 includes an internal ground plane that grounds traces in contact with the plane. In one embodiment, the second midlayer 132 and the third midlayer 133 facilitate the manufacture of the IC package 100. For example, the IC package 100 is manufactured initially as three double-sided boards, each corresponding the top layer 130, the second midlayer 132, and the third midlayer 133. In one embodiment, the fourth midlayer 134 corresponds to a layer carrying 3.3 volts (3V3) or 1.8 volts (1V8), for example.

To vertically connect the components on each of these layers, embodiments of the IC package 100 include any number of vias 142. In one example “vias” refer to conductive paths, such as the illustrated vertical conductive paths, that form layer-to-layer connections in the IC package. In a first example, the via 142 corresponds to blind vias 142A that extend from a surface layer (such as the illustrated top layer 130 or the bottom layer 136) to the next corresponding layer. The illustrated example includes a blind via 142A extending from the top layer 130 to the first midlayer 131 that is adjacent to the top layer 130. In a second example, the via 142 corresponds to a buried via 142B that extends between two internal layers that are not surface layers. The illustrated example includes the buried via 142B extending from the second midlayer 132 to the third midlayer 133. In a third example, the via 142 corresponds to a through-hole via 142C that extends from the top layer 131 to the bottom layer 136 through the height of the IC package 100. For example, the through-hole via 142C is formed by drilling through the layers after the layers have been fabricated and the routing etched, and then conductive via barrels are formed in the drilled holes using any suitable process, such as an electroless plating process.

Turning to FIG. 1C, illustrated are two traces 150 carrying respective signals, in accordance with aspects of the technology described herein. The illustrated embodiment includes a first trace 150 that corresponds to a through-hole via 142C carrying a first signal, and a second trace 150B that corresponds to a through-hole via 142C carrying a second signal. As illustrated, the traces 150 include stacked vias 152. For example, the first trace 150A includes a first set of stacked vias 152A, and the second trace 150B includes a second set of stacked vias 152B. In one embodiment, the first and second traces 150A and 150B carry respective signals to or from a receiver or transceiver. For example, the first trace 150A carries and communicates the first signal to or from a land grid array (LGA) 154. In one example, the LGA 154 is a type of surface-mount packaging for IC packages and that has pins or a grid of contacts on a socket (as opposed to the pins being on the IC, known as a “pin grid array” [PGA]). As illustrated, the second trace 150B carries and communicates a second signal to a ball grid array (BGA) 156. In one example, a BGA 156 is a type of surface-mount packaging for IC packages and that has balls forming contacts. Although the traces 150 are shown as being coupled to certain types of grid arrays, it should be understood that the embodiments disclosed herein are not limited to the LGA, PGA, or BGA disclosed herein.

In certain IC packages 100 (FIGS. 1A and 1B), the traces 150 carry signals from a transceiver (sending the signal) to a receiver intended to receive the signal. For example, a vertical conductive path of the trace is segmented into an upper and a lower part. In this example, the lower part is connected to its neighboring signal's upper part through a trace, and the neighboring signal does the same. In certain IC packages 100, the close proximity of two or more traces 150 (in this example, the two or more vias 142) cause crosstalk, such as FEXT, between the two or more traces 150. Embodiments of the present disclosure reduce or substantially eliminate the FEXT.

FIG. 2A depicts a schematic diagram showing a portion of an IC package 200 having two traces 150 that form a coupling trace pair 202 having an out-of-phase coupling relationship, in accordance with aspects of the technology described herein. In one example, the out-of-phase coupling occurs because the direction of the first signal travels along the same direction as the second signal except in coupling region 202 where the two signals travel in opposite directions. For example, the first signal and the second signal travel downward from the first segment to the third segment, as described herein. FIG. 2B depicts the flow of current between these two traces within a portion of an IC package 204. In one embodiment, the illustrated first trace 150A and the second trace 150B of FIGS. 2A and 2B correspond to the first trace 150A and the second trace 150B of FIG. 1C. To facilitate discussion, FIGS. 2A and 2B are described in parallel.

As illustrated, the first trace 150A extends between a first end and a second end, such that the first signal travels from the first end to the second end or from the second end to the first end. The illustrated first trace 150A has a shape defined by a first segment 211, a second segment 212, and a third segment 213. Similarly, the illustrated second trace 150B extends between a corresponding first end and a corresponding second end, such that the second signal travels from the corresponding first end to the corresponding second end or from the corresponding second end to the corresponding first end. The illustrated second trace 150B has a shape defined by a corresponding first segment 221, a corresponding second segment 222, and a corresponding third segment 223. However, the embodiments disclosed herein are not limited to traces 150 having three segments, as these embodiments can be implemented by traces 150 having more or fewer segments.

In one embodiment, the first trace 150A and the second trace 150B are substantially parallel to each other and are in close proximity to each other. For example, a vertical conductive path of the trace is segmented into an upper part (corresponding to the first segments 211 and 221) and a lower part (corresponding to the third segments 213 and 223). In one embodiment, the lower part of one signal is connected to its neighboring signal's upper part through a trace, and the neighboring signal does the same. In one embodiment, the two connecting traces are in parallel, and the spacing between the second segment 212 and the corresponding second segment 222 is very small (for example, less than or equal to 50 microns, such as 50 microns, 30 microns, 25 microns, 15 microns, and so forth or any value in between) or tightly coupled. In the trace coupling section 202, the two signals run in opposite directions.

In one embodiment, a first distance between the first segment 211 of the first trace 150A and the corresponding first segment 221 of the second trace 150B is larger than a second distance between the second segment 212 of the first trace 150A and the corresponding second segment 222 of the second trace 150B. In one embodiment, a third distance between the third segment 213 of the first trace 150A and the corresponding third segment 223 of the second trace 150B is larger than the second distance.

In some embodiments, the second signal traveling along the second trace 150B as current 230 causes a first induced current (not shown in FIG. 2A) to be induced in the IC package 200, for example, in a component separate from the illustrated first trace 150A or second trace 150B. For example, the first current is induced in other parts of the IC package 200, printed circuit board, connectors, or any other locations other than the location at which the coupling trace pairs 202 are formed. In one example, “current” includes alternating current (AC) or direct current (DC). In this example, the second trace 150B is the aggressor that induces the first induced current, which travels along the first trace 150A through electromagnetic coupling at locations other than the illustrated coupling trace pair 202. In this example, the first trace 150A is the victim trace. In some instances, the first induced current causes FEXT. To reduce this FEXT, in one embodiment, the corresponding second segment 222 of the second trace 150B electromagnetically couples with the second segment 212 of the first trace 150A to reduce a far-end crosstalk (FEXT) associated with the first induced current. In one embodiment, the FEXT associated with the first induced current is reduced by controlling the second signal (for example, current 230) to cause the second signal to travel along the corresponding second segment 222 in a direction that induces a second induced current 232 in the second segment 212 of the first trace 150A. In this example, the second induced current 232 is induced in a direction and/or with a magnitude opposite of the first induced current (for example, induced current) traveling along the second segment 212 of the first trace 150A, thereby canceling out the induced current and reducing FEXT. As described herein, the electromagnetic coupling of the second segments 212 and 222 generates a crosstalk canceling pulse having an amplitude substantially similar and a polarity opposite of the first induced current that is causing the FEXT between the first trace 150A and the second trace 150B.

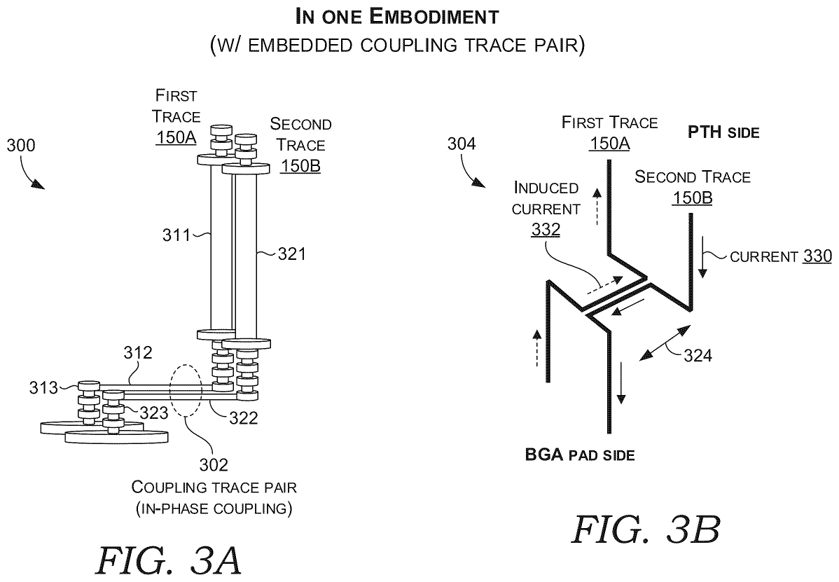

FIG. 3A depicts a schematic diagram showing a portion of an IC package 300 having two traces 150 that form a coupling trace pair 302 having an in-phase coupling relationship 302, in accordance with aspects of the technology described herein. In one example, the in-phase coupling occurs because the first signal travels in the same direction as the second signal, including in the coupling region 302. For example, whereas the first signal travels downward from the first segment 311 to the third segment 313 of the first trace 150A, the second signal travels downward from the first corresponding segment 321 to the third corresponding segment 323 of the second trace 150B, as described below. FIG. 3B depicts a schematic diagram of a system 304 showing the flow of current between the two traces of FIG. 3A that form a coupling trace pair 302 having the in-phase coupling relationship, in accordance with aspects of the technology described herein. FIGS. 3A and 3B are described in parallel.

As illustrated, the first trace 150A extends between a first end and a second end, such that the first signal travels from one end to the other. The illustrated first trace 150A has a shape defined by a first segment 311, a second segment 312, and a third segment 313. Similarly, the illustrated second trace 150B extends between a corresponding first end and a corresponding second end, such that the second signal travels from one end to the other in a direction that is the same as that of the first signal. The illustrated second trace 150B has a shape defined by a corresponding first segment 321, a corresponding second segment 322, and a corresponding third segment 323. However, the embodiments disclosed herein are not limited to traces 150 having three segments, as these embodiments can be implemented by traces 150 having more or fewer segments. In one embodiment, the length of the second segment 312 or of the corresponding second segment 322 corresponds to a distance offset 324 between two components. For example, the distance offset 324 defines a distance separating a portion of the IC 100 corresponding to a BGA pad and another portion of the IC 100 corresponding to a port through-hole (PTH) side.

In one embodiment, the first trace 150A and the second trace 150B are substantially parallel to each other and are in close proximity to each other. For example, a vertical conductive path of the trace is segmented into an upper part (corresponding to the first segments 311 and 321) and a lower part (corresponding to the third segments 313 and 323). In one embodiment, the two connecting traces are in parallel and the spacing between the second segment 312 and the corresponding second segment 322 is very small (for example, less than or equal to 50 microns, such as 50 microns, 30 microns, 25 microns, 15 microns, and so forth or any value in between) or tightly coupled. In the trace coupling section 302, the two signals run in the same direction.

In some embodiments, the second signal traveling along the second trace 150B as current 330 causes a first induced current (not shown in FIG. 2A) to be induced in the IC package 300, for example, in a component separate from the illustrated first trace 150A or second trace 150B. For example, the first current is induced in other parts of the IC package 200, printed circuit board, connectors, or any other locations other than the location at which the coupling trace pairs 302 are formed. In this example, the second trace 150B is the aggressor that induces the first induced current in the first trace 150A, which is the victim trace. In some instances, the first induced current causes FEXT. To reduce this FEXT, in one embodiment, the corresponding second segment 322 of the second trace 150B electromagnetically couples with the second segment 312 of the first trace 150A to reduce a far-end crosstalk (FEXT) associated with the first induced current. In one embodiment, the FEXT associated with the first induced current is reduced by controlling the second signal (for example, current 330) to cause the second signal to travel along the corresponding second segment 222 in a direction that induces a second induced current 332 in the second segment 212 of the first trace 150A. In this example, the second induced current 332 is induced as a crosstalk canceling pulse in a direction and/or with a magnitude opposite of the first induced current traveling along the second segment 312 of the first trace 150A, thereby canceling out the induced current and reducing FEXT. As described herein, the electromagnetic coupling of the second segments 312 and 322 includes controlling a parameter of the aggressor trace (in this example, the second trace 150B), for example, to generate a crosstalk canceling pulse having an amplitude substantially similar and a polarity opposite of the first induced current that is causing the FEXT between the first trace 150A and the second trace 150B.

To electromagnetically couple the first and second trace, in FIG. 3A and FIG. 3B, in the illustrated example the first segments 311 and 321 are repositioned or rearranged to increase their respective distances; the third segments 313 and 323 are repositioned or rearranged to increase their distance; and the second segments 312 and 322 are repositioned or rearranged to be in close proximity to each other (as a coupling trace pair 302) with a distance between them much smaller than that between the first segments 311 and 321 and the third segments 313 and 323.

As illustrated, the polarities of the crosstalk canceling pulse of the aggressor traces in FIGS. 2A and 2B are different as compared to those in FIGS. 3A and 3B. For example, the polarity of the crosstalk canceling pulse is positive for the out-of-phase coupling relationship shown in FIGS. 2A and 2B, and the polarity of the crosstalk canceling pulse is negative for the in-phase coupling shown in FIGS. 3A and 3B. The opposite polarity can be explained by Lenz's law and the difference in positioning of the first and third segments of the two traces 150 between FIGS. 2A and 2B, as well as FIGS. 3A and 3B. For example, and as illustrated in FIG. 2A, the out-of-phase coupling relationship created by the aggressor current induces, in the trace coupling section 202, a current (shown with a dashed line) running in an opposite direction in the neighboring trace according to electromagnetism, as set forth by Lenz's Law. In the illustrated first segments 211 and 221 (which in one example correspond to a via or pin through-hole) and in the illustrated third segments 213 and 223, the induced current is in the same direction as the aggressor current. On the contrary, in in-phase coupling shown in FIGS. 3A and 3B, the induced current is opposite to the aggressor current in the first segments 311 and 321 and in the illustrated third segments 313 and 323. In this example, the difference in the direction of the induced current explains the difference in the polarity of the crosstalk canceling pulse. Generating a crosstalk canceling pulse with an amplitude the same as that of (and in the opposite direction of) the induced current can cause the magnitude of the resulting FEXT to be near zero.

In more detail, the difference in the polarity can be explained with reference to equation 1 below.

$$FEXT = \frac{1}{2} ( \frac{length}{v \times {t}_{r}} ) ( \frac{C m}{C} - \frac{L m}{L} ) , \qquad ( 1 )$$

where FEXT refers to the far-end crosstalk, length refers to the length of a trace, ν refers to propagation speed of a signal running in the trace, tᵣ is the rise time of the signal, C is self-capacitance of a trace, Cm is the mutual capacitance between traces, L is inductance of a trace, and Lm is the mutual inductance between traces. In some instances, most of the FEXT is a result of the mutual capacitance and mutual inductance between traces. Embodiments of the present disclosure generate the crosstalk canceling pulse to make the difference between the two ratios in equation 1 near zero. When the difference between the ratios is zero, the FEXT is also near zero. In some embodiments, the width of the trace, the distance between the traces, the material of the trace, or the length of the trace is changed to achieve a desired crosstalk canceling pulse and to reduce FEXT. For example, the length of the trace is based on a (1) distance between the first segment and the corresponding first segment, as well as a (2) distance between the third segment and the corresponding third segment (of the arrangement in FIG. 2A) and their respective proximity. In this example, increasing the length of the second segments can reduce a FEXT by generating a stronger crosstalk canceling pulse. Accordingly, certain embodiments of the present disclosure reduce a difference between a first ratio and a second ratio, such that the first ratio is a ratio between a mutual capacitance of the first and second signal paths and a self-capacitance of the first signal path or the second signal path, and the second ratio is a ratio between a mutual inductance of the first and second signal paths and a self-inductance of the first path or the second signal path. In this example, the first and second traces are part of the first and second signal path, respectively.

Although this example has one trace inducing a current in the other trace (in this example, the second trace 150B inducing a current in the first trace 150A), it should be understood that in some embodiments both traces 150 simultaneously induce currents of different magnitudes and/or directions in each other. Additionally, any group of traces can induce a current in any number of neighboring traces. For example, two neighboring traces can induce respective currents in one trace, such that one of the neighboring traces is configured to generate a crosstalk canceling pulse.

Moreover, the shape of the traces 150 is not limited to the three-segment shape illustrated in FIGS. 2A, 2B, 3A, and 3B. For example, certain embodiments discussed herein can be implemented in any place along or proximate to the trace, such as a die, a conductive path of a silicon chip, a package, an interposer, a PCB, a connector, a cable, or any other component of the IC package. The shape of the trace can be any suitable shape, such as variations of serpentine, zigzag, loop, and the like, on the same layer, along a vertical direction, or on two adjacent layers.

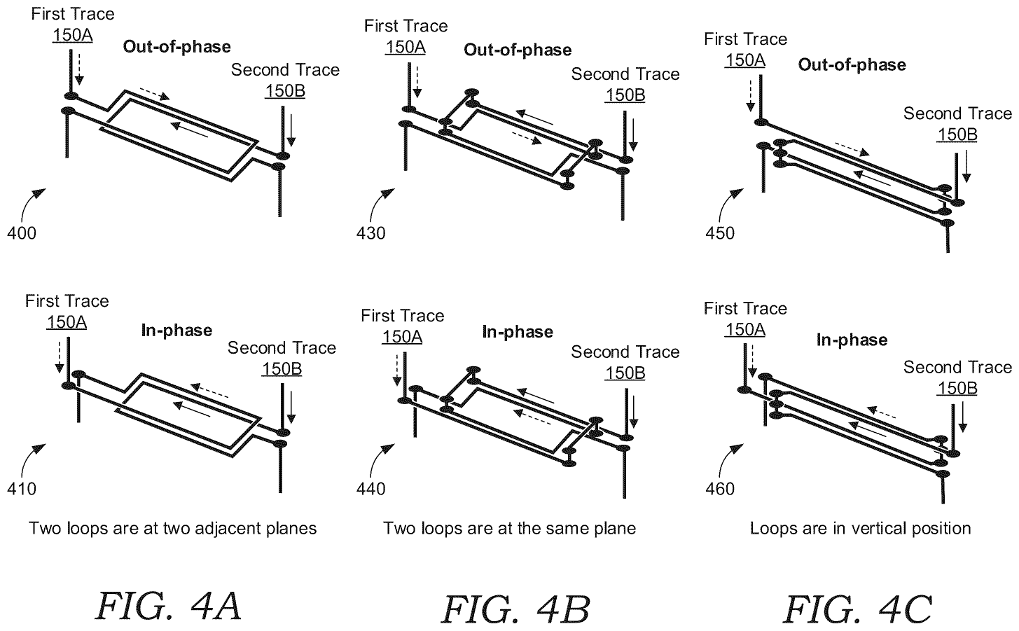

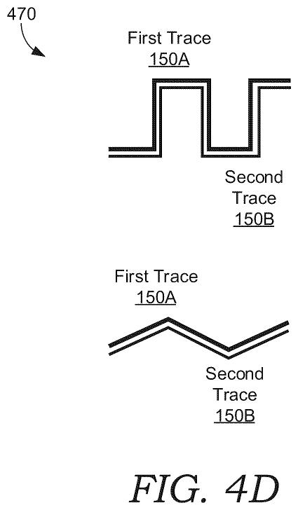

As a first example, FIG. 4A depicts a schematic diagram showing two different sets of traces 150 that form a respective coupling trace pair and that have two loops at two adjacent planes, in accordance with aspects of the technology described herein. In FIG. 4A, a first coupling trace pair 400 has a first trace 150A and a second trace 150B arranged in an out-of-phase coupling relationship, and a second coupling trace pair 410 has a first trace 150A and a second trace 150B arranged in an in-phase coupling relationship. In FIG. 4A, the coupling trace pairs 400 and 410 each include two loops in two adjacent vertical planes. In this example, the vertical planes are parallel to each other and are at different positions along the vertical direction (defined as being along one end of the trace 150 to the other end of the trace 150).

As a second example, FIG. 4B depicts a schematic diagram showing two different sets of traces 150 that form a respective coupling trace pair and that have two loops on the same plane, in accordance with aspects of the technology described herein. In FIG. 4B, a third coupling trace pair 430 has a first trace 150A and a second trace 150B arranged in an out-of-phase coupling relationship, and a fourth coupling trace pair 440 has a first trace 150A and a second trace 150B arranged in an in-phase coupling relationship. In FIG. 4A, the coupling trace pairs 430 and 440 each include two loops arranged on the same vertical planes. In this example, the vertical plane is orthogonal to a vertical direction (defined as being along one end of the trace 150 to the other end of the trace 150).

As a third example, FIG. 4C depicts a schematic diagram showing two different sets of traces 150 that form a respective coupling trace pair and that have two loops each at distinct vertical positions, in accordance with aspects of the technology described herein. In FIG. 4C, a fifth coupling trace pair 450 has a first trace 150A and a second trace 150B arranged in an out-of-phase coupling relationship, and a sixth coupling trace pair 460 has a first trace 150A and a second trace 150B arranged in an in-phase coupling relationship. In FIG. 4Cs, the coupling trace pairs 450 and 460 each include two loops with portions at different vertical positions and on separate planes. In this example, the vertical direction is defined as being along one end of the trace 150 to the other end of the trace 150. As illustrated, the first trace 150A has a loop with segments that are at the same horizontal plane with corresponding segments of the second trace 150B.

As a fourth example, FIG. 4D depicts a schematic diagram showing respective pairs 470 of traces 150 that form a coupling trace pair and that have coupling trace pairs with sharp corners, in accordance with aspects of the technology described herein. For example, the illustrated first trace 150A and second trace 150B have sharp edges and form a coupling pair due to their close proximity to each other. It should be understood that in some embodiments, the coupling pair of traces 150 include any suitable shape, such as a shape having sharp edges arranged in any suitable configuration, a shape having round edges, or any combination thereof.

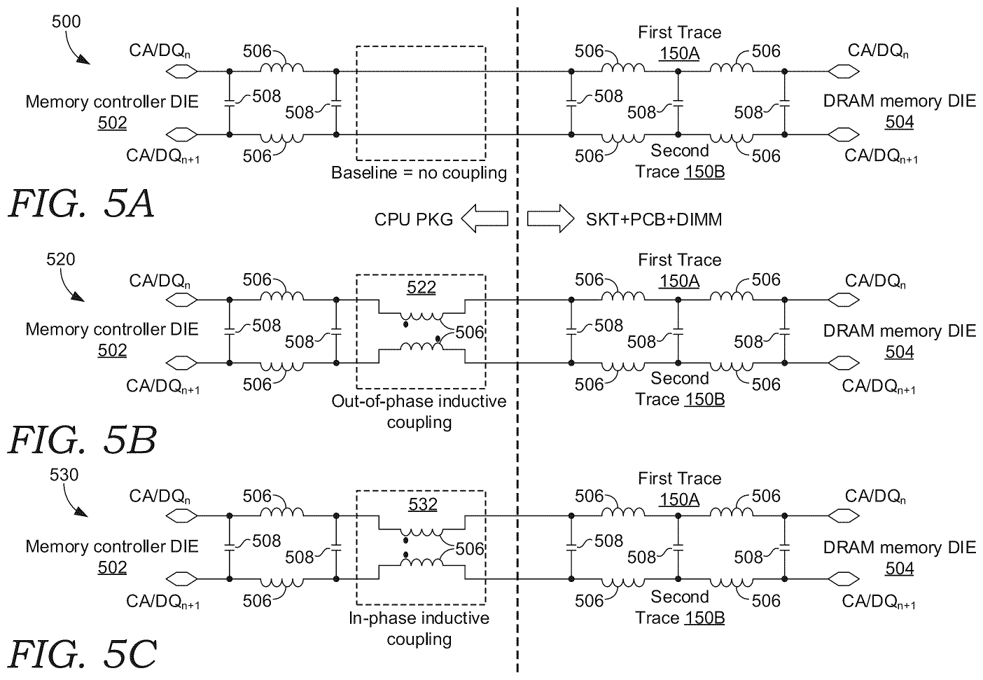

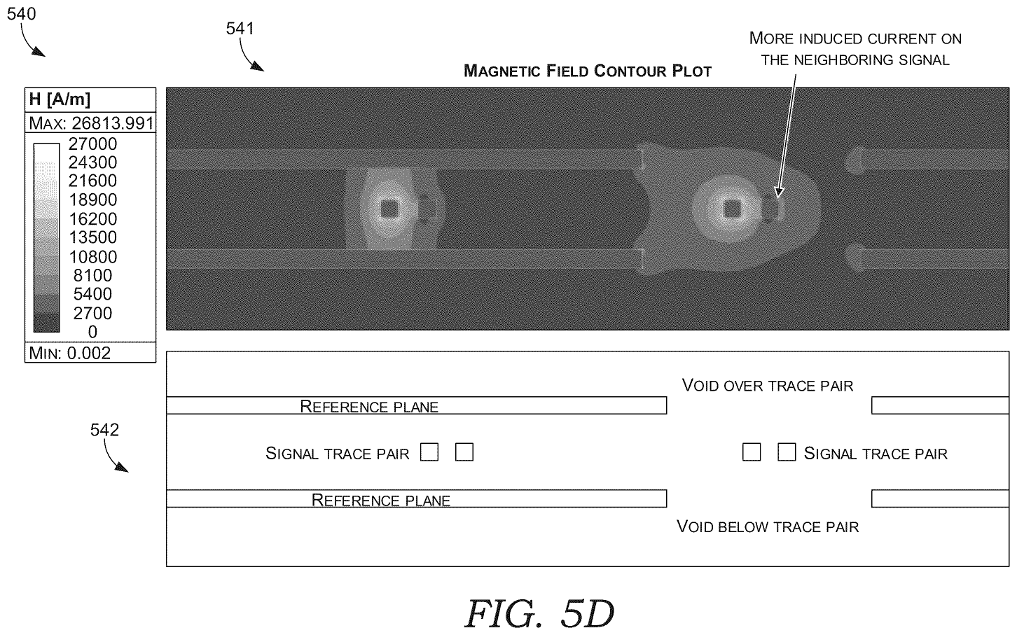

FIG. 5A depicts a first circuit diagram 500 showing a first trace 150A and a second trace 150B that are not electromagnetically coupled in the segments highlighted by the dashed rectangular box, in accordance with aspects of the technology described herein. In other words, in FIG. 5A, neither of the traces 150 generate a crosstalk canceling pulse because the first trace 150A and the second trace 150B of FIG. 5A are not in an in-phase or out-of-phase coupling relationship in the segment highlighted by the dashed rectangular box. In one example, the traces 150A and 150B correspond to two DDR traces that connect a memory controller die 502 (which can correspond to a portion of the memory controller 110 of FIG. 1) to a DRAM controller die 504 (which can correspond to a portion of the DRAM 120 of FIG. 1). In one example, the first circuit diagram 500 corresponds to a circuit diagram associated with the arrangement of traces 150 illustrated in FIG. 1C. As shown in the first circuit diagram 500, the two traces 150A and 150B have one or more inductors 506 and one or more capacitors 508. In one embodiment, the one or more inductors 506 or capacitors in one trace 150 induce a current in the other trace 150.

FIG. 5B depicts a second circuit diagram 520 showing a first trace 150A and a second trace 150B that are electromagnetically coupled in an out-of-phase inductive relationship 522 in the segments highlighted by the dashed rectangular box, in accordance with aspects of the technology described herein. In this example, the polarity of the inductors indicates the coupling is out-of-phase. In other words, in FIG. 5B, at least one of the traces 150A and 150B generates a crosstalk canceling pulse to reduce a crosstalk associated with a current induced in the other trace, as a result of the out-of-phase coupling relationship 522. In one example, the crosstalk includes FEXT that is induced as a result of one or more inductors 506 or capacitors 508 in a neighboring trace 150. In one example, the traces 150A and 150B correspond to two DDR traces that connect a memory controller die 502 (which can correspond to a portion of the memory controller 110 of FIG. 1) to a DRAM controller die 504 (which can correspond to a portion of the DRAM 120 of FIG. 1). In one example, the second circuit diagram 520 corresponds to a circuit diagram associated with the arrangement of traces 150 illustrated in FIGS. 3A and 3C. In one example, the out-of-phase coupling relationship 522 is created by the trace coupling pair 202 of FIGS. 2A and 2B.

FIG. 5C depicts a third circuit diagram 530 showing a first trace 150A and a second trace 150B that are inductively coupled in an in-phase inductive coupling relationship 532 in the segments highlighted by the dashed rectangular box, in accordance with aspects of the technology described herein. In this example, the polarity of the inductors indicates the coupling is in-phase. In other words, in FIG. 5C, at least one of the traces 150A and 150B generates a crosstalk canceling pulse to reduce a crosstalk associated with a current induced in the other trace as a result of the in-phase coupling relationship 532. In one example, the crosstalk includes FEXT that is induced as a result of one or more inductors 506 or capacitors 508 in a neighboring trace 150. In one example, the traces 150A and 150B correspond to two DDR traces that connect a memory controller die 502 (which can correspond to a portion of the memory controller 110 of FIG. 1) to a DRAM controller die 504 (which can correspond to a portion of the DRAM 120 of FIG. 1). In one example, the third circuit diagram 530 corresponds to a circuit diagram associated with the arrangement of traces 150 illustrated in FIGS. 3A and 3B. In one example, the in-phase coupling relationship 532 is created by the trace coupling pair 302 of FIGS. 3A and 3B.

Turning to FIG. 5D, depicted is a heat map 540 of two magnetic field contour plots 541 and 542 associated with the second circuit diagram of FIG. 5B or the third circuit diagram of FIG. 5C, in accordance with aspects of the technology described herein. The illustrated first magnetic field contour plot 541 shows how “voiding” enhances the electromagnetic coupling between two traces, such as the first trace 150A and the second trace 150B discussed herein. In one example, “voiding” refers to the presence of metal gaps in metal layers of packages or printed circuit boards during metal etching process. In another example, “voiding” refers to the presence of air pockets or gaps in solder joints made during the soldering process. In the first and second magnetic contour plots 542 and 543, traces with and without voiding are shown side by side. The trace without voiding is shown on the left and the trace with voiding is shown on the right.

The illustrated second magnetic contour plot 542 shows how a coupling trace, such as the coupling traces 202 of FIG. 2 and the coupling traces 302, enhance the electromagnetic coupling between the two traces 150A and 150B. With reference to the second magnetic contour plot 542, on the left, the traces have solid reference planes above and below the trace pair. Continuing with the second magnetic contour plot 542, on the right, the plane above and below the traces are voided. The illustrated first magnetic field contour plot 541 shows the magnetic field distribution when the left conductor is injected with an alternate current having an amplitude of 1 amp (A) and a frequency of 3.6 gigahertz (GHz). With continued reference to the first magnetic field contour plot 541, in the voiding case on the right, the victim trace has more induced current from the inductive coupling (with the aggressor trace) as compared to that of the non-voiding case. Accordingly, in some embodiments voiding is employed to increase the electromagnetic coupling between traces because in some instances, voiding increases the coupling between the two traces, as show in the two magnetic field contour plots 541 and 542.

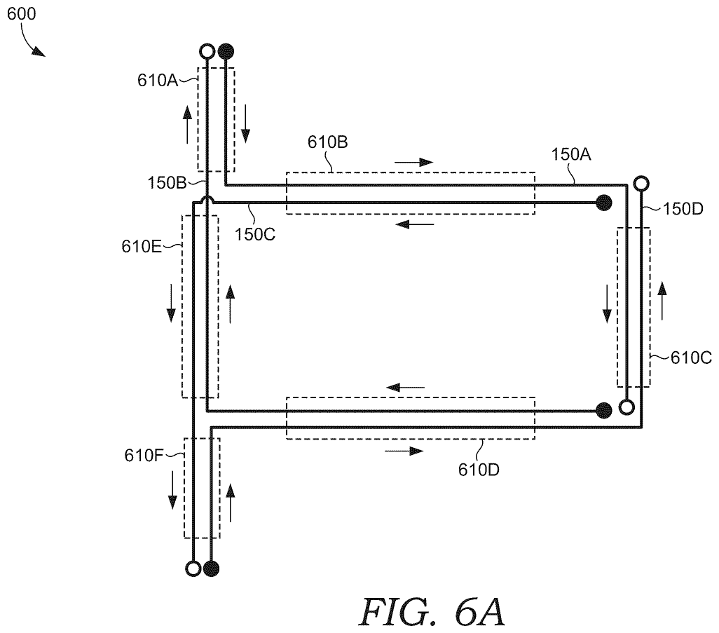

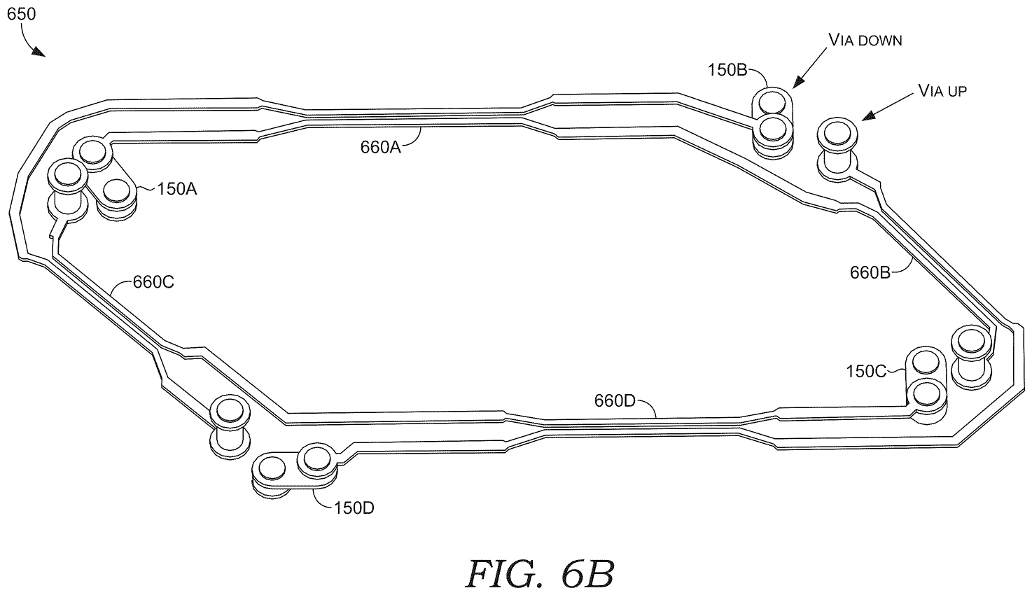

FIG. 6A depicts a schematic diagram of a system 600 including a plurality of traces that each form a plurality of coupling trace pairs 610, in accordance with aspects of the technology described herein. The illustrated system 600 includes four traces 150, namely, the first trace 150A, the second trace 150B, the third trace 150C, and the fourth trace 150D. Each of the illustrated traces 150 has a transmitter, at one end, labeled with the solid circle, and a receiver at another end labeled with a hollow circle. In this example, the arrows show the direction of current flow. With reference to the first trace 150A, in this example the first trace 150A forms a first coupling trace pair 610A with the second trace 150B, forms a second coupling trace pair 610B with the third trace 150C, and forms a third coupling trace pair 610C with the fourth trace 150D. In one embodiment, the first coupling trace pair 610A electromagnetically couples the first trace 150A and the second trace 150B, the second coupling trace pair 610B electromagnetically couples the first trace 150A and the third trace 150C, and the third coupling trace pair 610 electromagnetically couples the first trace 150A and the fourth trace 150D.

In one embodiment, the signal traveling through first trace 150A includes a crosstalk canceling pulse having an amplitude substantially similar and a polarity opposite of the FEXT between the first trace 150A and the second trace 150B (caused by a current induced in the second trace 150B by the first trace 150A), the FEXT between the first trace 150A and the third trace 150C (caused by a current induced in the third trace 150C by the first trace 150A), and the FEXT between the first trace 150A and the fourth trace 150D (caused by a current induced in the fourth trace 150D by the first trace 150A). In one embodiment, the second trace 150B also communicates a signal having an amplitude and a polarity opposite the FEXT between the second trace 150B and the first trace 150A (caused by a current induced in the first trace 150A by the second trace 150B). Any number of traces can employ the embodiments disclosed herein to reduce FEXT caused from a current induced by or into any number of neighboring traces. For example, by employing the electromagnetic coupling disclosed herein, FEXTs can be reduced by the electromagnetic coupling caused in association with the illustrated first coupling trace pair 610A, the second coupling trace pair 610B, the third coupling trace pair 610C, the fourth coupling trace pair 610D, the fifth coupling trace pair 610E, and the sixth coupling trace pair 610F.

FIG. 6B depicts a schematic diagram of a system 650 including a plurality of traces 150 that each form two coupling trace pairs 660, in accordance with aspects of the technology described herein. The illustrated system 650 includes four traces 150, namely, the first trace 150A, the second trace 150B, the third trace 150C, and the fourth trace 150D. In one embodiment, each of the traces 150 has a transmitter at one end and a receiver at another end. In system 650, “via up” refers to a trace 150 forming a via path to upper package layers of an IC package and “via down” refers to a trace 150 forming a via path to BGA or LGA, for example, at the bottom of the package.

In some embodiments, implementing two coupling trace pairs 660 per trace causes two crosstalk reductions to occur per trace, for example, at each region having a coupling trace pair 660. In this example, suppose the first trace 150A and the third trace 150C direct current in a clockwise direction, and further suppose that the second trace 150B and the fourth trace 150D direct current in a counterclockwise direction. In this example, such arrangement enables out-of-phase electromagnetic coupling between the first trace 150A and the second trace 150B (labeled as the first coupling trace pair 660A); between the first trace 150A and the fourth trace 150D (labeled as the second coupling trace pair 660B); between the second trace 150B and the third trace 150C (labeled as the third coupling trace pair 660C); and between the third trace 150C and the fourth trace 150D (labeled as the fourth coupling trace pair 660D). With proper coupling lengths (or other modifications associated with the variables from equation 1 above), the FEXT can be reduced.

FIG. 7A depicts a schematic diagram of a first system 700 including two example differential pairs of traces that form a coupling trace pair between the two differential signal pairs, in accordance with aspects of the technology described herein. In one example, a “differential pair” includes at least two traces or at least two conductive paths, routed side-by-side, and that carry equal magnitude and opposite polarity signals on each trace. In one embodiment, differential pairs communicate binary information, or possibly multiple bits at once with a more advanced protocol like Pulse Amplitude Modulation 4-Level (PAM4). One difference between a standard digital trace and differential signaling is that a differential signal is recovered and interpreted in a different manner. The illustrated first system 700 includes a first differential pair 710 and a second differential pair 720. In this example, the first differential pair 710 has a first end on the left side at a higher elevation than the second end on the right side, and the second differential pair 720 has a first end on the right side at a higher elevation than the second end on the left side. In the example illustrated in FIG. 7A, when electrical current signals are injected into the first ends of both trace pairs, an out-of-phase coupling equivalents for differential signal pairs is created.

FIG. 7B depicts a schematic diagram of a second system 728 including two example differential pairs of traces, in accordance with aspects of the technology described herein. The illustrated second system 728 includes a third differential pair 730 and a fourth differential pair 740. In this example, the third differential pair 730 and the fourth differential pair each have a first end on the left side at a lower elevation than the second end on the right side. In the example illustrated in FIG. 7B, when electrical current signals are injected into the first ends of both trace pairs, an in-phase coupling equivalents for differential signal pairs is created.

In one example, the differential pairs in systems 700 or 728 induce a current in each other, causing FEXT. To reduce the FEXT, the differential pairs can form a set of coupling trace pairs 750, as illustrated. In this example, the set of coupling trace pairs 750 correspond to the portion of the trace pairs that is electromagnetically coupled to each other so as to reduce FEXT through the generation of a crosstalk canceling pulse. For example, in the first system 700, the set of coupling trace pairs 750 is the portions of each of the first and second differential pairs 710 and 720 that are in close proximity to each other, which in this example corresponds to the planar and centrally located portions of the differential pairs. For example, suppose the first differential pair 710 induces a first induced current in the second differential pair 720, thereby causing FEXT. In this example, the first differential pair 710 is controlled to generate a crosstalk canceling pulse that the coupling trace pairs 750 cause another current to be induced in the second differential pair in the opposite direction as the first induced current and with a substantially similar amplitude. In this manner, embodiments of the present disclosure reduce crosstalk even for systems carrying more complicated signals, such as those associated with differential pairs.

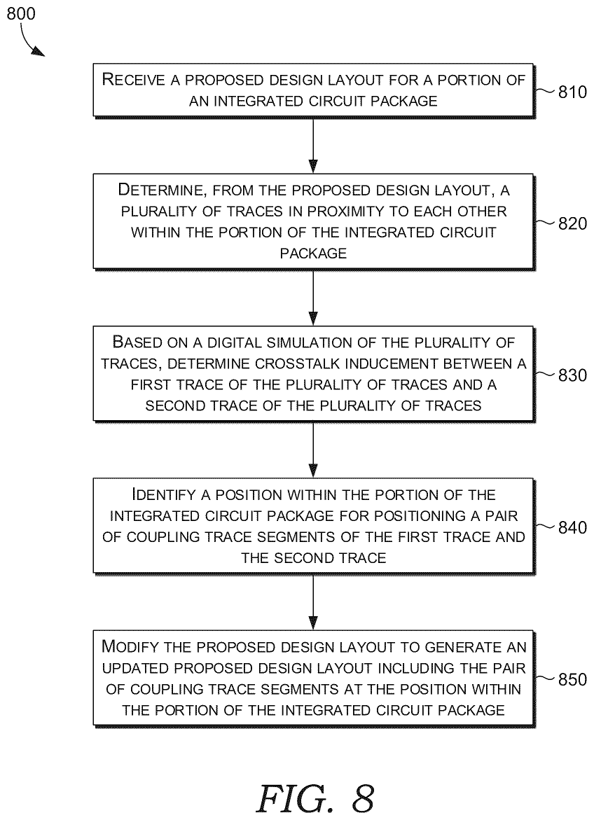

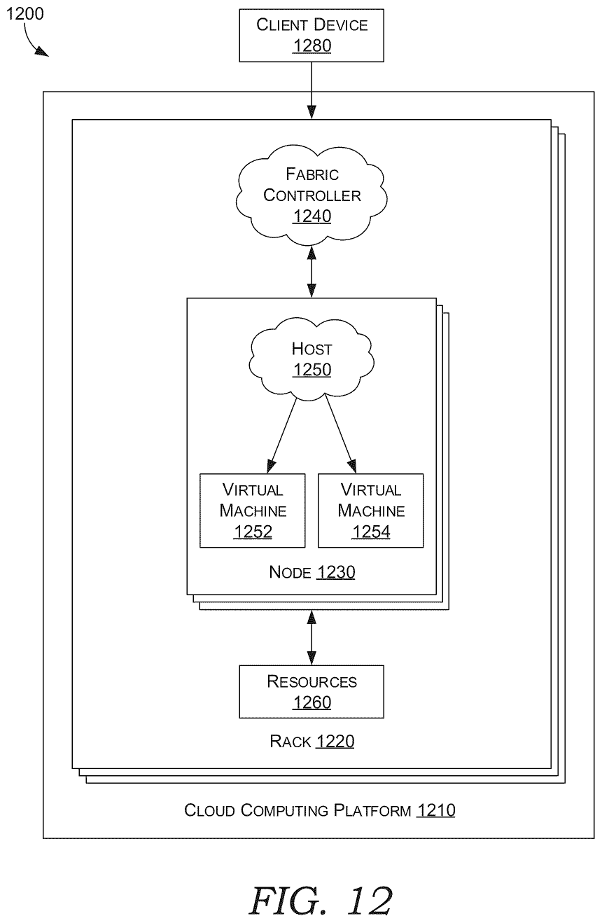

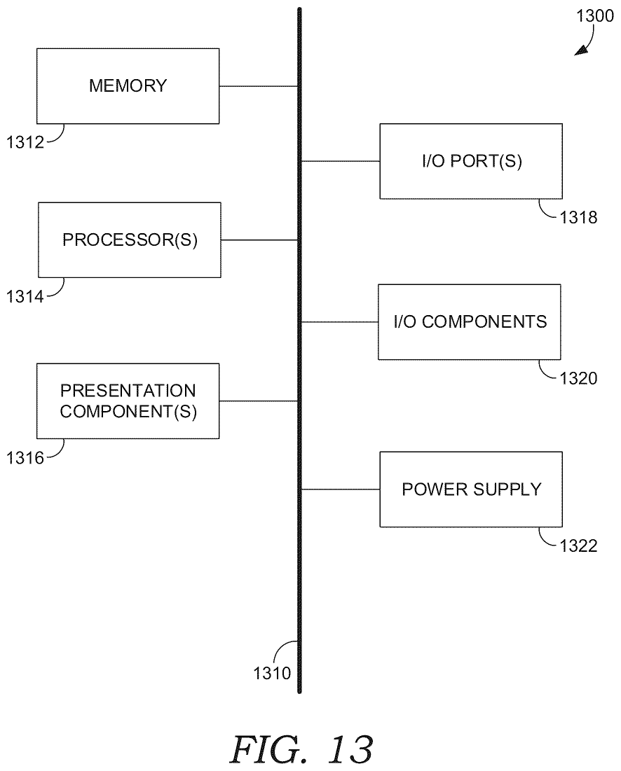

With reference to FIG. 8, a flow diagram is provided illustrating a method 800 to programmatically modify a proposed design layout of a PCB to generate an updated proposed design layout experiencing less FEXT as compared to the proposed design layout, in accordance with aspects of the technology described herein. In some embodiments, one or more components of the IC package 100 and/or the other elements described herein perform or benefit from aspects of the method illustrated in FIG. 8. In some embodiments, one or more computer storage media having computer-executable or computer-useable instructions embodied thereon that, when executed by one or more processors, cause the one or more processors to perform the method 800 or any embodiments disclosed herein. For example, method 800 is performed by the example distributed computing environment 1200 of FIG. 12 and/or the example computing device 1300 of FIG. 13.

Continuing with FIG. 8, at block 810, the process 800 includes receiving a proposed design layout for a portion of an integrated circuit package. For example, the portion of the integrated circuit package includes a trace, a silicon chip, a die, an interposer, a printed circuit board (PCB), a connector, or a cable. The proposed design layout may be received as a circuit diagram, such as that illustrated in FIG. 5A, 5B, or 5C, or may be received as a vector representation of the components in the portion of the IC package. At block 820, process 800 includes determining, from the proposed design layout, a plurality of traces in proximity to each other within the portion of the integrated circuit package. At block 830, process 800 includes determining, based on a digital simulation of the plurality of traces, crosstalk inducement between a first trace of the plurality of traces and a second trace of the plurality of traces. At block 840, process 800 includes identifying a position within the portion of the integrated circuit package for positioning a pair of coupling trace segments of the first trace and the second trace so as to reduce the crosstalk induced between the first trace and the second trace, as discussed herein.

At block 850, process 800 includes modifying the proposed design layout to generate an updated proposed design layout, including the pair of coupling trace segments at the position within the portion of the integrated circuit package. This modification can include rearranging at least one existing trace of the plurality of traces without adding another trace. In one embodiment, a signal density of the updated proposed design layout matches a signal density of the proposed design layout. In one embodiment, modifying the proposed design layout includes changing at least one of: a length of the first trace or the second trace, a width of the first trace or the second trace, or a material of the first trace or the second trace. In one embodiment, modifying the proposed design layout includes electromagnetically coupling a segment of the first trace with a segment of the second trace to reduce a far-end crosstalk (FEXT) (1) between the first trace and the second trace and (2) that is caused by a first induced current in the segment of the first trace. In this example, a signal of the first trace is controllable to cause the signal to travel along the segment of the first trace in a direction that induces, in the segment of the second trace, a second induced current in a direction opposite of the first induced current.

### Example Reduction to Practice

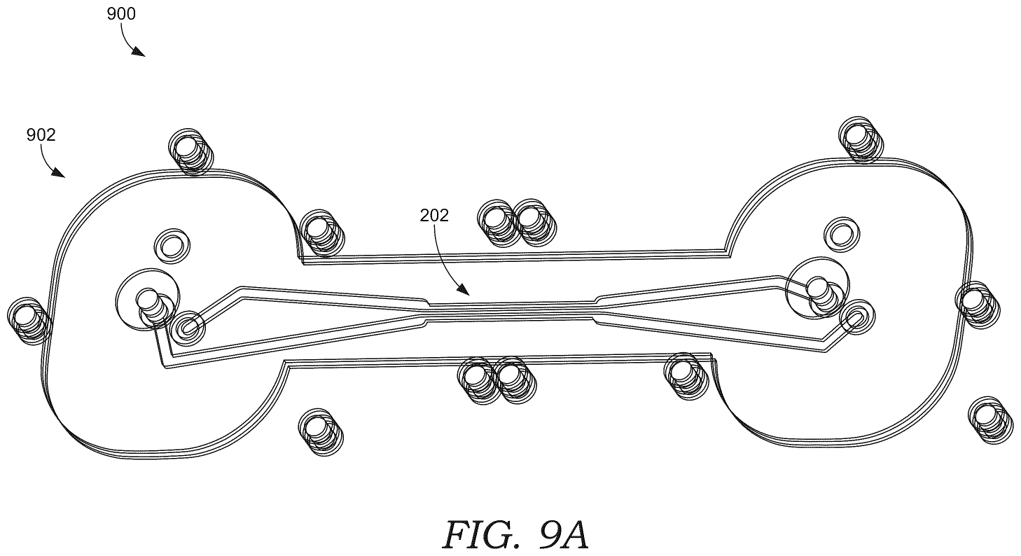

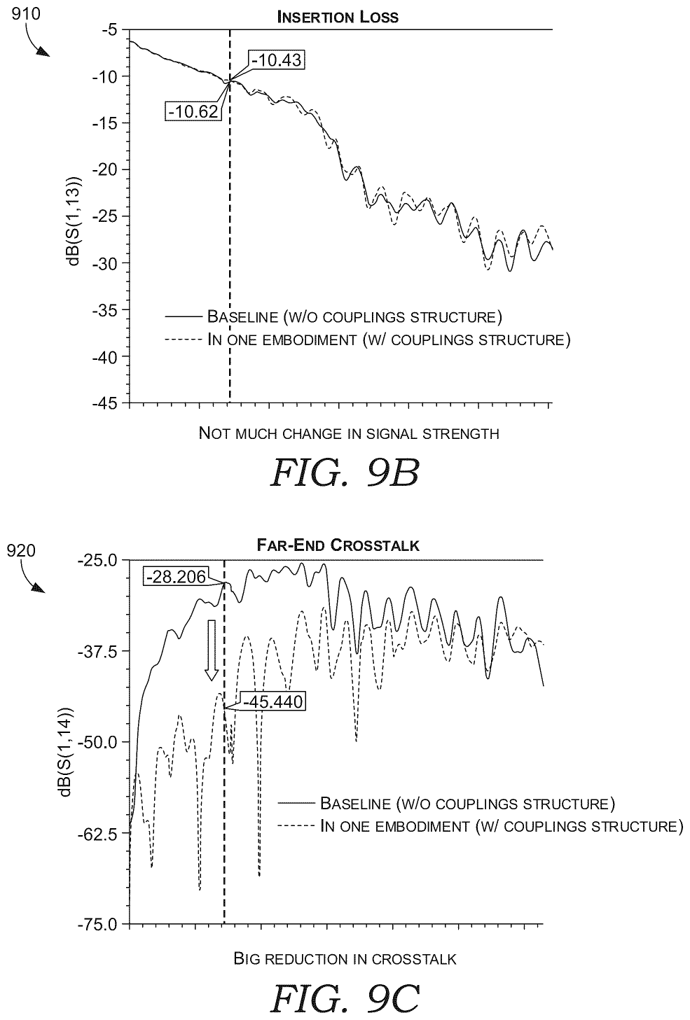

An illustrative example embodiment of the present disclosure that has been reduced to practice is described herein. This example embodiment comprises an out-of-phase coupling 202 (similar to that of FIG. 2), as described herein, applied to the IC package 902 illustrated in FIG. 9A. Tests or simulations were performed on this IC package 902 to generate the plots or graphs depicted in FIGS. 9B, 9C, 10A, 10B, 11A, and 11B. However, it should be noted that although this example reduction-to-practice focuses specifically on a specific implementation, embodiments of the technologies described herein are more generally applicable to other electronic devices, including those that communicate any suitable signals, such as SDR, DDR, or QDR, to name a few.

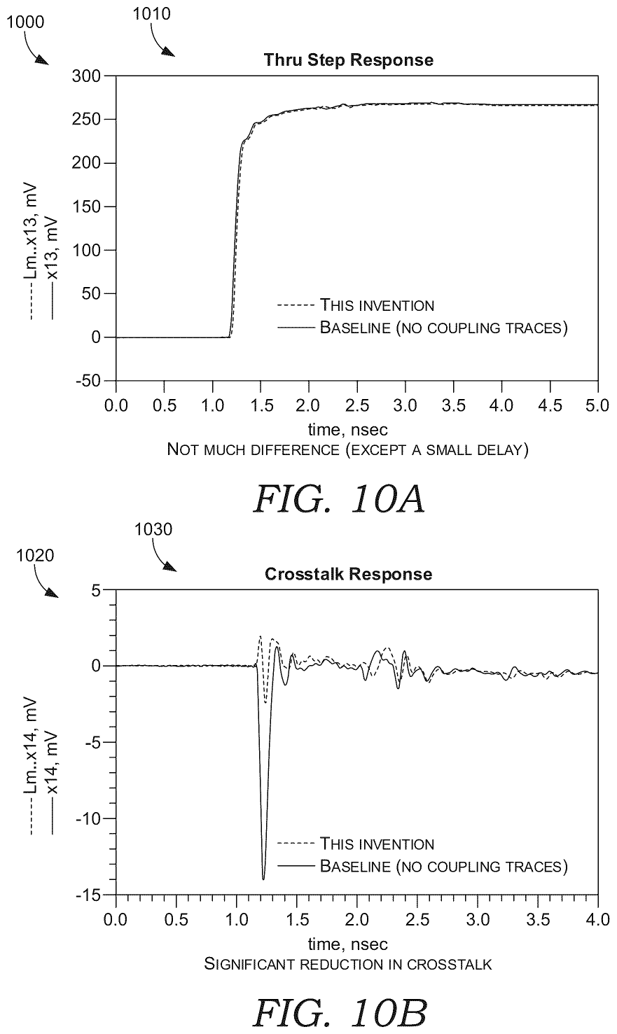

With reference to FIGS. 1 through 7B, and with continuing reference to process 800 of FIG. 8, respectively, the IC package 902 was constructed, tested, and verified as described below. In FIG. 9A, an example IC package 902 was tested and simulated as a high-frequency structure simulator (HFSS) in environment 900 in accordance with aspects of the technology described herein. In this example, two traces were repositioned so that they formed a coupling trace pair 202. For example, the IC package 902 was constructed with a coupling trace pair 202 having a portion of the traces coming within 0.05 mm of each other, a distance much closer than the distance of the traces in other portions of the HFSS model. As part of the testing and simulation, insertion loss 910 was plotted in the first plot 912 of FIG. 9B; FEXT 920 was plotted in the second plot 922 of FIG. 9C; a step thru response 1000 was plotted in the third plot 1010 of FIG. 10A; and a crosstalk response 1020 was plotted in the fourth plot 1030.

With reference to FIG. 9B, in the first plot 912, the insertion loss 910 remained relatively the same between an IC package that does not include a coupling trace pair (plotted as a solid line) and another IC package that does include a coupling trace pair 202 (FIG. 9A) (plotted as a dashed line). With reference to FIG. 9C, in the second plot 922, the FEXT 920 is lower for the IC package that includes the coupling trace pair 202 (FIG. 9A) as compared to the IC package that did not include the coupling trace pair. In particular, the second plot 922 shows that the FEXT was reduced by about 17 decibels (dBs) in the frequency domain. With reference to FIG. 10A, the third plot 1010 shows a through-step response 1000 of an extracted S-parameter of the DDR channel that includes the IC package with the coupling trace pair 202 (FIG. 9A) and the DDR channel that did not include the coupling trace pair. As illustrated, the full-channel S-parameter was substantially the same between the IC package that included the coupling trace pair 202 (FIG. 9A) and the IC package that did not include the coupling trace pair. With reference to the fourth plot 1030 of FIG. 10A, the peak magnitude of the crosstalk response 1020, measured as millivolts (mV), was higher for the IC package that does not include a coupling trace pair (plotted as a solid line) than another IC package that does include a coupling trace pair 202 (FIG. 9A) (plotted as a dashed line).

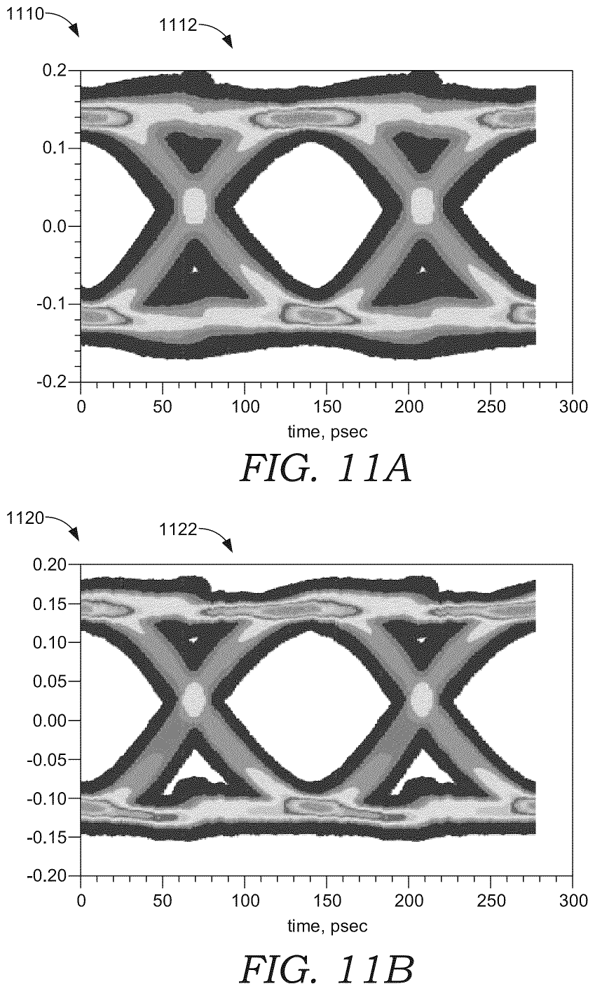

FIG. 11A depicts an eye diagram 1110 showing a time-domain simulation 1112 for a full-channel that does not employ aspects of the embodiments disclosed herein. That is, in FIG. 11A, results for an IC package that do not include a coupling trace pair are reproduced. On the other hand, FIG. 11B depicts an eye diagram 1120 showing a time-domain simulation 1122 for a full-channel corresponding to the example embodiment from FIG. 9A that has been reduced to practice, tested, and simulated. That is, in FIG. 11B, results for an IC package that includes a coupling trace pair (for example, having a coupling trace pair that induced an inductive effect) are reproduced. In these time-domain simulations 1112 and 1122, the worst bit of the full-channel was examined. In these eye diagrams 1110 and 1120, the full-channel corresponds to a trace leading from a central processing unit (CPU) die to a DRAM die. As compared to the eye diagram 1110 of FIG. 11A, the eye diagram 1120 of FIG. 11B showed improved eye opening, less jittery transition edges for the bit stream in the DDR WRITE direction.

As a result, testing confirmed that FEXT was reduced between the first trace and the second trace, and computing performance improved by employing the coupling trace pairs. This improvement was achieved by controlling one trace to cause a signal to travel along the trace in a direction that induces, in another trace, an induced current in a direction opposite of an initial induced current that was causing the FEXT. Accordingly, the simulation and testing of an embodiment reduced to practice confirmed that aspects of this disclosure improve the signal-to-noise ratio of a memory bus.

### OTHER EMBODIMENTS

In some embodiments, an integrated circuit system is provided, employing any components of described in any of the embodiments above. The integrated circuit system comprises a first trace and a second trace. The first trace, within the integrated circuit system, extends between a first end and a second end, and has a shape defined by a first segment, a second segment, and a third segment. A first signal travels along the first trace from the first end to the second end. The second trace extends between a corresponding first end and a corresponding second end; and has a shape defined by a corresponding first segment, a corresponding second segment, and a corresponding third segment. A first induced current in the second trace is induced by the first signal traveling along the first trace through electromagnetic coupling at a location other than the first trace and the second trace. The second segment of the first trace electromagnetically couples with the corresponding second segment of the second trace to reduce a far-end crosstalk (FEXT) associated with the first induced current in the second trace by controlling the first signal to cause the first signal to travel along the second segment in a direction that induces a second induced current in the corresponding second segment of the second trace. The second induced current is induced in a direction opposite of the first induced current traveling along the corresponding second segment of the second trace.

In any combination of the above embodiments of the integrated circuit system, the electromagnetic coupling of the second segment and the corresponding second segment generates a crosstalk canceling pulse having an amplitude substantially similar and a polarity opposite of the FEXT between the first trace and the second trace.

In any combination of the above embodiments of the integrated circuit system, the electromagnetic coupling of the second segment and the corresponding second segment forms an out-of-phase coupling between the first trace and the second trace.

In any combination of the above embodiments of the integrated circuit system, the electromagnetic coupling of the second segment and the corresponding second segment forms an in-phase coupling between the first trace and the second trace.

In any combination of the above embodiments of the integrated circuit system, a first distance between the first segment of the first trace and the corresponding first segment of the second trace is larger than a second distance between the second segment of the first trace and the corresponding second segment of the second trace, and wherein a third distance between the third segment of the first trace and the corresponding third segment of the second trace is larger than the second distance.

In any combination of the above embodiments of the integrated circuit system, the second distance is less than 50 microns, and wherein at least one of the first distance or the third distance is greater than 300 microns.

In any combination of the above embodiments of the integrated circuit system, the electrical coupling of the corresponding second segment of the second trace and the second segment of the first trace reduces a difference between a first ratio and a second ratio. The first ratio is a ratio between a mutual capacitance of first and second signal paths and a self-capacitance of the first signal path or the second signal path. The second ratio is a ratio between a mutual inductance of the first and second signal paths and a self-inductance of the first signal path or the second signal path. The first signal path comprises the first trace and the second signal path comprises the second trace.

In any combination of the above embodiments of the integrated circuit system, the integrated circuit system includes a third trace extending between a respective first end and a respective second end. The third trace has a shape defined by a respective first segment, a respective second segment, and a respective third segment. A third current travels along the third trace. One of the segments of the third trace electrically couples with at least one of the first segment of the first trace, the third segment of the first trace, the corresponding first segment of the second trace, or the corresponding third segment of the second trace to reduce a FEXT between the third trace and at least one of the first trace or the second trace.

In any combination of the above embodiments of the integrated circuit system, the first trace comprises a plurality of conductive paths extending between the first end and the second end, and wherein the second trace comprises a plurality of corresponding conductive paths.

In any combination of the above embodiments of the integrated circuit system, the first signal and the first induced current comprise a corresponding electrical current, and wherein the first trace and the second trace comprise a respective conductive path.

In any combination of the above embodiments of the integrated circuit system, the coupling between the first trace and the second trace is mutual and the crosstalk cancellation is also mutual. For example, a third induced current induced by the second trace on the first trace also get cancelled by a fourth induced current generated by the second trace on the first trace.

In some embodiments, a computer-implemented method is provided. The computer-implemented method includes receiving a proposed design layout for a portion of an integrated circuit package; determining, from the proposed design layout, a plurality of traces in proximity to each other within the portion of the integrated circuit package; based on a digital simulation of the plurality of signal paths comprising the plurality of traces, determining crosstalk inducement between a first signal path of the plurality of signal paths and a second signal path of the plurality of signal paths; identifying a position within the portion of the integrated circuit package for positioning a pair of coupling trace segments of the first trace and the second trace; and modifying the proposed design layout to generate an updated proposed design layout including the pair of coupling trace segments at the position within the portion of the integrated circuit package.

In any combination of the above embodiments of the computer-implemented method, modifying the proposed design layout comprises changing at least one of: a length of the first trace or the second trace, a distance between the first trace and the second trace, a width of the first trace or the second trace, or a material of the first trace or the second trace.

In any combination of the above embodiments of the computer-implemented method, modifying the proposed design layout comprises rearranging at least one existing trace of the plurality of traces without adding another trace.

In any combination of the above embodiments of the computer-implemented method, the portion of the integrated circuit package comprises at least one of a trace, a silicon chip, a die, an interposer, a printed circuit board (PCB), a connector, or a cable.

In any combination of the above embodiments of the computer-implemented method, a signal density of the updated proposed design layout matches a signal density of the proposed design layout.

In any combination of the above embodiments of the computer-implemented method, modifying the proposed design layout comprises electromagnetically coupling a segment of the first trace with a segment of the second trace to reduce a far-end crosstalk (FEXT) (1) between the first trace and the second trace and (2) that is caused by a first induced current in the segment of the first trace. A signal of the first trace is controllable to cause the signal to travel along the segment of the first trace in a direction that induces, in the segment of the second trace, a second induced current in a direction opposite of the first induced current.

In some embodiments, an electrical system is provided, employing any components of the systems described in any of the embodiments above. The electrical system comprises a first trace and a second trace. The first trace extends between a first end and a second end, and has a shape defined by a first segment and a second segment. A first signal travels along the first trace from the first end to the second end. The second trace extends between a corresponding first end and a corresponding second end, has a shape defined by a corresponding first segment and a corresponding second segment. A first induced current in the second trace is induced by the first signal traveling along the first trace through electromagnetic coupling at a location other than the first trace or the second trace. The corresponding second segment of the second trace electromagnetically couples with the second segment of the first trace to reduce a far-end crosstalk (FEXT) between the first trace and the second trace by controlling the first signal to cause the first signal to travel along the second segment in a direction that induces a second induced current in the corresponding second segment of the second trace. The second induced current is induced in a direction opposite of the first induced current traveling along the corresponding second segment of the second trace.

In any combination of the above embodiments of the electrical system, the electrical system further includes at least one of an integrated circuit package or a printed circuit board that comprises the first trace and the second trace.

In any combination of the above embodiments of the electrical system, at least one of the first trace or the second trace comprises a lead that electrically couples a first component of an integrated circuit package of the electrical system to a second component external to the integrated circuit package.

In any combination of the above embodiments of the electrical system, the electrical system comprises a first electrical component and a second electrical component, wherein at least one of the first trace or the second trace has a conductive path connecting the first electrical component and the second electrical component within the electrical system.

### Example Computing Environment

Having described various implementations, example computing environments suitable for implementing embodiments of the disclosure are now described, including an example distributed computing environment and an example computing device in FIGS. 12 and 13 respectively. Embodiments of the disclosure are described in the general context of computer code or machine-useable instructions, including computer-useable or computer-executable instructions, such as program modules, being executed by a computer or other machine such as a smartphone, a tablet, personal computer (PC), or other mobile device, server, or client device. Generally, program modules, including routines, programs, objects, components, data structures, and the like, refer to code that performs particular tasks or implements particular abstract data types. Embodiments of the disclosure are practiced in a variety of system configurations, including mobile devices, consumer electronics, general-purpose computers, more specialty computing devices, or the like. Embodiments of the disclosure are also practiced in distributed computing environments where tasks are performed by remote-processing devices that are linked through a communications network. In a distributed computing environment, program modules may be located in both local and remote computer storage media including memory storage devices.

Some embodiments comprise an end-to-end software-based system that can operate within system components described herein to operate computer hardware to provide system functionality. At a low level, hardware processors may execute instructions selected from a machine language (also referred to as machine code or native) instruction set for a given processor. The processor recognizes the native instructions and performs corresponding low-level functions relating to, for example, logic, control, and memory operations. Low-level software written in machine code can provide more complex functionality to higher levels of software. Accordingly, in some embodiments, computer-executable instructions include any software, including low-level software written in machine code, higher level software such as application software, and any combination thereof. In this regard, the system components can manage resources and provide services for system functionality. Any other variations and combinations thereof are contemplated with the embodiments of the present disclosure.

Referring now to FIG. 12, FIG. 12 illustrates an example distributed computing environment 1200 in which implementations of the present disclosure can be employed. In particular, FIG. 12 shows a high-level architecture of an example cloud computing platform 1210 that can host a technical solution environment or a portion thereof (e.g., a data trustee environment). It should be understood that this and other arrangements described herein are set forth only as examples. For example, as described above, many of the elements described herein are implemented as discrete or distributed components or in conjunction with other components, and in any suitable combination and location. Other arrangements and elements (e.g., machines, interfaces, functions, orders, and groupings of functions) can be used in addition to or instead of those shown.

Data centers can support distributed computing environment 1200, which includes cloud computing platform 1210, rack 1220, and node 1230 (e.g., computing devices, processing units, or blades) in rack 1220. The technical solution environment can be implemented with cloud computing platform 1210 that runs cloud services across different data centers and geographic regions. Cloud computing platform 1210 can implement a fabric controller 1240 component for provisioning and managing resource allocation, deployment, upgrade, and management of cloud services. Typically, cloud computing platform 1210 acts to store data or run service applications in a distributed manner. Cloud computing platform 1210 in a data center can be configured to host and support operation of endpoints of a particular service application. Cloud computing platform 1210 may be a public cloud, a private cloud, or a dedicated cloud.

Node 1230 can be provisioned with host 1250 (e.g., operating system or runtime environment) running a defined software stack on node 1230. Node 1230 can also be configured to perform specialized functionality (e.g., compute nodes or storage nodes) within cloud computing platform 1210. Node 1230 is allocated to run one or more portions of a service application of a tenant. A tenant can refer to a customer utilizing resources of cloud computing platform 1210. Service application components of cloud computing platform 1210 that support a particular tenant can be referred to as a multi-tenant infrastructure or tenancy. The terms service application, application, or service are used interchangeably herein and broadly refer to any software, or portions of software, that run on top of storage, access storage, and compute device locations within a datacenter.

When more than one separate service application is being supported by nodes 1230, nodes 1230 may be partitioned into virtual machines (e.g., virtual machine 1252 and virtual machine 1254). Physical machines can also concurrently run separate service applications. The virtual machines or physical machines can be configured as individualized computing environments that are supported by resources 1260 (e.g., hardware resources and software resources) in cloud computing platform 1210. It is contemplated that resources can be configured for specific service applications. Further, each service application may be divided into functional portions such that each functional portion is able to run on a separate virtual machine. In cloud computing platform 1210, multiple servers may be used to run service applications and perform data storage operations in a cluster. In particular, the servers may perform data operations independently but be exposed as a single device referred to as a cluster. Each server in the cluster can be implemented as a node.

Client device 1280 may be linked to a service application in cloud computing platform 1210. Client device 1280 may be any type of computing device, which may correspond to computing device 1000 described with reference to FIG. 10. For example, client device 1280 is configured to issue commands to cloud computing platform 1210. In embodiments, client device 1280 communicates with service applications through a virtual Internet Protocol (IP) and load balancer or other means that direct communication requests to designated endpoints in cloud computing platform 1210. The components of cloud computing platform 1210 may communicate with each other over a network (not shown), which may include, without limitation, one or more local area networks (LANs) and/or wide area networks (WANs).

With reference to FIG. 13, an example computing device is provided and referred to generally as computing device 1300. The computing device 1300 is but one example of a suitable computing environment and is not intended to suggest any limitation as to the scope of use or functionality of embodiments of the disclosure, and nor should the computing device 1300 be interpreted as having any dependency or requirement relating to any one or combination of components illustrated. Computing device 1300 includes bus 1310 that directly or indirectly couples the following devices: memory 1312, one or more processors 1314, one or more presentation components 1316, input/output ports 1318, input/output components 1320, and illustrative power supply 1322. Bus 1310 represents what may be one or more buses (such as an address bus, data bus, or combination thereof). The various blocks of FIG. 13 are shown with lines for the sake of conceptual clarity, and other arrangements of the described components and/or component functionality are also contemplated. A presentation component, such as a display device, is an example of an I/O component. Also, processors have memory. It is recognized that such is the nature of the art, and it is reiterated that the diagram of FIG. 13 is merely illustrative of an example computing device that can be used in connection with one or more embodiments of the present disclosure. Distinction is not made between such categories as “workstation,” “server,” “laptop,” “handheld device,” etc., as all are contemplated within the scope of FIG. 13 and with reference to “computing device.”

Computing device 1300 typically includes a variety of computer-readable media. Computer-readable media can be any available media that can be accessed by computing device 1300 and includes both volatile and non-volatile media, removable and non-removable media. By way of example, and not limitation, computer-readable media include computer storage media and communication media. Computer storage media includes volatile and non-volatile, removable and non-removable media implemented in any method or technology for the storage of information, such as computer-readable instructions, data structures, program modules or other data. Computer storage media includes, but is not limited to, RAM, read-only memory (ROM), electronically erasable programmable read-only memory (EEPROM), flash memory or other memory technology, CD-ROM, digital versatile disks (DVDs) or other optical disk storage, magnetic cassettes, magnetic tape, magnetic disk storage or other magnetic storage devices, or any other medium that can be used to store the desired information and which can be accessed by computing device 1300. Computer storage media excludes signals per se. Communication media typically embodies computer-readable instructions, data structures, program modules, or other data in a modulated data signal such as a carrier wave or other transport mechanism and includes any information delivery media. The term “modulated data signal” indicates a signal that has one or more of its characteristics set or changed in such a manner so as to encode information in the signal. By way of example, and not limitation, communication media includes wired media such as a wired network or direct-wired connection, and wireless media such as acoustic, radio frequency (RF), infrared, and other wireless media. Combinations of any of the above should also be included within the scope of computer-readable media.

Memory 1312 includes computer storage media in the form of volatile and/or non-volatile memory. The memory may be removable, non-removable, or a combination thereof. Example hardware devices include solid-state memory, hard drives, optical-disc drives, etc. Computing device 1300 includes one or more processors that read data from various entities such as memory 1312 or I/O components 1320. As used herein, the term processor or “a processor” may refer to more than one computer processor. In one example, the term processor (or “a processor”) refers to at least one processor, which may be a physical or virtual processor, such as a computer processor on a virtual machine. The term processor (or “a processor”) also may refer to a plurality of processors, each of which may be physical or virtual, such as a multiprocessor system, distributed processing or distributed computing architecture, cloud computing system, or parallel processing by more than a single processor. Further, various operations described herein as being executed or performed by a processor may be performed by more than one processor.

Presentation component(s) 1316 present data indications to a user or other device. Example presentation components include a display device, speaker, printing component, vibrating component, etc.

I/O ports 1318 allow computing device 1300 to be logically coupled to other devices, including I/O components 1320, some of which may be built-in. Illustrative components include a microphone, joystick, game pad, satellite dish, scanner, printer, wireless device, etc.

### Additional Structural and Functional Features of Embodiments of the Technical Solution

Having identified various components utilized herein, it should be understood that any number of components and arrangements may be employed to achieve the desired functionality within the scope of the present disclosure. For example, the components in the embodiments depicted in the figures are shown with lines for the sake of conceptual clarity. Other arrangements of these and other components may also be implemented. For example, although some components are depicted as single components, many of the elements described herein may be implemented as discrete or distributed components or in conjunction with other components, and in any suitable combination and location. Some elements may be omitted altogether. Moreover, various functions described herein as being performed by one or more entities may be carried out by hardware, firmware, and/or software, as described herein. For instance, various functions may be carried out by a processor executing instructions stored in memory. As such, other arrangements and elements (e.g., machines, interfaces, functions, orders, and groupings of functions) can be used in addition to or instead of those shown.

Embodiments described herein may be combined with one or more of the specifically described alternatives. In particular, an embodiment that is claimed may contain a reference, in the alternative, to more than one other embodiment. The embodiment that is claimed may specify a further limitation of the subject matter claimed.

The subject matter of embodiments of this disclosure is described with specificity herein to meet statutory requirements. However, the description itself is not intended to limit the scope of this patent. Rather, this disclosure contemplates that the claimed subject matter might also be embodied in other ways to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

For purposes of this disclosure, “substantially,” when used to describe a level of proximity or similarity, generally refers to a group of elements sharing a level of distance proximity or degree of similarity. For example, a polarity of a crosstalk canceling pulse being substantially of a similar amplitude to an induced current indicates that the crosstalk canceling pulse and the induced current have a similar magnitude or amplitude (expressed as a percentage, ratio, threshold number, and so forth, such as 50%, 60%, 70%, 80%, 90%, 95%, 98%, 99%, 100%, and the like). To further clarify, in one example, a first trace 150A and the second trace 150B are substantially parallel to each other when both are 170, 173, 75, 185, 188, 190, or 180 degrees from each other.

For purposes of this disclosure, the word “including” has the same broad meaning as the word “comprising,” and the word “accessing” comprises “receiving,” “referencing,” or “retrieving.” Further, the word “communicating” has the same broad meaning as the word “receiving” or “transmitting” facilitated by software or hardware-based buses, receivers, or transmitters using communication media described herein. In addition, words such as “a” and “an,” unless otherwise indicated to the contrary, include the plural as well as the singular. Thus, for example, the constraint of “a feature” is satisfied where one or more features are present. Also, the term “or” includes the conjunctive, the disjunctive, and both (a or b thus includes either a or b, as well as a and b).

For purposes of a detailed discussion above, embodiments of the present disclosure are described with reference to a distributed computing environment; however, the distributed computing environment depicted herein is merely an example. Components can be configured for performing novel aspects of embodiments, where the term “configured for” can refer to “programmed to” perform particular tasks or implement particular abstract data types using code. Further, while embodiments of the present disclosure generally refer to the technical solution environment and the schematics described herein, it is understood that the techniques described may be extended to other implementation contexts.

As used herein, the terms “application” or “app” may be employed interchangeably to refer to any software-based program, package, or product that is executable via one or more (physical or virtual) computing machines or devices. An application may be any set of software products that, when executed, provide an end-user with one or more computational and/or data services. In some embodiments, an application may refer to a set of applications that may be executed together to provide the one or more computational and/or data services. The applications included in a set of applications may be executed serially, in parallel, or any combination thereof. The execution of multiple applications (comprising a single application) may be interleaved. For example, an application may include a first application and a second application. An execution of the application may include the serial execution of the first and second applications or a parallel execution of the first and second applications. In other embodiments, the execution of the first and second applications may be interleaved.

Embodiments of the present disclosure have been described in relation to particular embodiments which are intended in all respects to be illustrative rather than restrictive. Alternative embodiments will become apparent to those of ordinary skill in the art to which the present disclosure pertains without departing from its scope.

From the foregoing, it will be seen that this disclosure is one well-adapted to attain all the ends and objects hereinabove set forth together with other advantages which are obvious and which are inherent to the structure.

It will be understood that certain features and subcombinations are of utility and may be employed without reference to other features or subcombinations. This is contemplated by and is within the scope of the claims.

What is claimed is:

1. An integrated circuit system, comprising:
a first trace within the integrated circuit system and extending between a first end and a second end, the first trace having a shape defined by a first segment, a second segment, and a third segment, wherein a first signal travels along the first trace from the first end to the second end; and
a second trace extending between a corresponding first end and a corresponding second end, the second trace having a shape defined by a corresponding first segment, a corresponding second segment, and a corresponding third segment, wherein a first induced current in the second trace is induced by the first signal traveling along the first trace through electromagnetic coupling at a location other than the first trace and the second trace, and wherein the second segment of the first trace electromagnetically couples with the corresponding second segment of the second trace to reduce a far-end crosstalk (FEXT) associated with the first induced current in the second trace by controlling the first signal to cause the first signal to travel along the second segment in a direction that induces a second induced current in the corresponding second segment of the second trace, the second induced current being induced in a direction opposite of the first induced current traveling along the corresponding second segment of the second trace.

2. The integrated circuit system of claim 1, wherein the electromagnetic coupling of the second segment and the corresponding second segment generates a crosstalk canceling pulse having an amplitude substantially similar and a polarity opposite of the FEXT between the first trace and the second trace.

3. The integrated circuit system of claim 1, wherein the electromagnetic coupling of the second segment and the corresponding second segment forms an out-of-phase coupling between the first trace and the second trace.

4. The integrated circuit system of claim 1, wherein the electromagnetic coupling of the second segment and the corresponding second segment forms an in-phase coupling between the first trace and the second trace.

5. The integrated circuit system of claim 1, wherein a first distance between the first segment of the first trace and the corresponding first segment of the second trace is larger than a second distance between the second segment of the first trace and the corresponding second segment of the second trace, and wherein a third distance between the third segment of the first trace and the corresponding third segment of the second trace is larger than the second distance.

6. The integrated circuit system of claim 5, wherein the second distance is less than 50 microns, and wherein at least one of the first distance or the third distance is greater than 300 microns.

7. The integrated circuit system of claim 1, wherein the electrical coupling of the corresponding second segment of the second trace and the second segment of the first trace reduces a difference between a first ratio and a second ratio, wherein the first ratio is a ratio between a mutual capacitance of first and second signal paths and a self-capacitance of the first signal path or the second signal path, wherein the second ratio is a ratio between a mutual inductance of the first and second signal paths and a self-inductance of the first signal path or the second signal path, wherein the first signal path comprises the first trace and the second signal path comprises the second trace.

8. The integrated circuit system of claim 1, comprising a third trace extending between a respective first end and a respective second end, the third trace having a shape defined by a respective first segment, a respective second segment, and a respective third segment, wherein a third current travels along the third trace, and wherein one of the segments of the third trace electrically couples with at least one of the first segment of the first trace, the third segment of the first trace, the corresponding first segment of the second trace, or the corresponding third segment of the second trace to reduce a FEXT between the third trace and at least one of the first trace or the second trace.

9. The integrated circuit system of claim 1, wherein the first trace comprises a plurality of conductive paths extending between the first end and the second end, and wherein the second trace comprises a plurality of corresponding conductive paths.

10. The integrated circuit system of claim 1, wherein the first signal and the first induced current comprise a corresponding electrical current, and wherein the first trace and the second trace comprise a respective conductive path.

11. A computer-implemented method, comprising:
receiving a proposed design layout for a portion of an integrated circuit package;
determining, from the proposed design layout, a plurality of traces in proximity to each other within the portion of the integrated circuit package;
based on a digital simulation of the plurality of signal paths comprising the plurality of traces, determining crosstalk inducement between a first signal path of the plurality of signal paths and a second signal path of the plurality of signal paths;
identifying a position within the portion of the integrated circuit package for positioning a pair of coupling trace segments of a first trace and a second trace of the plurality of traces; and
modifying the proposed design layout to generate an updated proposed design layout including the pair of coupling trace segments at the position within the portion of the integrated circuit package.

12. The computer-implemented method of claim 11, wherein modifying the proposed design layout comprises changing at least one of: a length of the first trace or the second trace, a distance between the first trace and the second trace, a width of the first trace or the second trace, or a material of the first trace or the second trace.

13. The computer-implemented method of claim 11, wherein modifying the proposed design layout comprises rearranging at least one existing trace of the plurality of traces without adding another trace.

14. The computer-implemented method of claim 11, wherein the portion of the integrated circuit package comprises at least one of a trace, a silicon chip, a die, an interposer, a printed circuit board (PCB), a connector, or a cable.

15. The computer-implemented method of claim 11, wherein a signal density of the updated proposed design layout matches a signal density of the proposed design layout.

16. The computer-implemented method of claim 11, wherein modifying the proposed design layout comprises electromagnetically coupling a segment of the first trace with a segment of the second trace to reduce a far-end crosstalk (FEXT) (1) between the first trace and the second trace and (2) that is caused by a first induced current in the segment of the first trace, wherein a signal of the first trace is controllable to cause the signal to travel along the segment of the first trace in a direction that induces, in the segment of the second trace, a second induced current in a direction opposite of the first induced current.

17. An electrical system, comprising:
a first trace, extending between a first end and a second end, and having a shape defined by a first segment and a second segment, wherein a first signal travels along the first trace from the first end to the second end; and
a second trace extending between a corresponding first end and a corresponding second end, the second trace having a shape defined by a corresponding first segment and a corresponding second segment, wherein a first induced current in the second trace is induced by the first signal traveling along the first trace through electromagnetic coupling at a location other than the first trace or the second trace, and wherein the corresponding second segment of the second trace electromagnetically couples with the second segment of the first trace to reduce a far-end crosstalk (FEXT) between the first trace and the second trace by controlling the first signal to cause the first signal to travel along the second segment in a direction that induces a second induced current in the corresponding second segment of the second trace, the second induced current being induced in a direction opposite of the first induced current traveling along the corresponding second segment of the second trace.

18. The electrical system of claim 17, comprising at least one of an integrated circuit package or a printed circuit board that comprises the first trace and the second trace.

19. The electrical system of claim 17, wherein at least one of the first trace or the second trace comprises a lead that electrically couples a first component of an integrated circuit package of the electrical system to a second component external to the integrated circuit package.

20. The electrical system of claim 17, wherein the electrical system comprises a first electrical component and a second electrical component, wherein at least one of the first trace or the second trace has a conductive path connecting the first electrical component and the second electrical component within the electrical system.
